(19) United States
(12) Patent Application Publication
(10) Pub. No.: US 2021/0193633 A1
(43) Pub. Date: Jun. 24, 2021

(54) FRONT MEMBER OF LED DISPLAY AND METHOD FOR MANUFACTURING THEREOF

(71) Applicant: FUJIFILM Corporation, Tokyo (JP)

(72) Inventor: Hideyuki NAKAMURA, Shizuoka (JP)

(73) Assignee: FUJIFILM Corporation, Tokyo (JP)

(21) Appl. No.: 17/190,764

(22) Filed: Mar. 3, 2021

Related U.S. Application Data
(63) Continuation of application No. PCT/JP2019/032689, filed on Aug. 21, 2019.

(30) Foreign Application Priority Data
Sep. 28, 2018 (JP) 2018-183512

(51) Int. Cl. H01L 25/075; H01L 33/58

(52) U.S. Cl. CPC H01L 25/0753; H01L 33/58

(57) ABSTRACT

Provided are a front member of an LED display, which includes a support and a colored layer containing an organic resin and a carbon nano-tube and in which an uneven shape is provided on the surface of the colored layer opposite to the side on which the support is provided, and a method for manufacturing a front member of an LED display, which includes a step of forming a photosensitive layer on a support using a photosensitive composition containing at least one compound selected from the group consisting of a binder polymer and an ethylenic unsaturated compound, and a carbon nano-tube, a step of forming an uneven shape on the surface of the photosensitive layer opposite to the side on which the support is provided, and a step of patterning the photosensitive layer.

### CROSS-REFERENCE TO RELATED APPLICATIONS

This application is a continuation application of International Application No. PCT/JP2019/032689, filed Aug. 21, 2019, the disclosure of which is incorporated herein by reference in its entirety. Further, this application claims priority from Japanese Patent Application No. 2018-183512, filed Sep. 28, 2018, the disclosure of which is incorporated herein by reference in its entirety.

### BACKGROUND OF THE INVENTION

### 1. Field of the Invention

The present disclosure relates to a front member of an LED display and a method for manufacturing thereof.

### 2. Description of the Related Art

In an LED display, it is extremely important to reduce the specular reflectance of the image display unit from the viewpoint of improving the contrast and the image display quality.

For example, a black antireflection member is known as an antireflection member that prevents the reflection of light from an LED display.

Examples of the conventional method for forming a substrate having a black pattern include a method disclosed in JP2015-087409A.

JP2015-087409A discloses a method for manufacturing a substrate having a black pattern, which includes the following steps (1) and (2) and in which in a case where a laminate having a black pattern formed in the step (2) is heat-treated at 200° C. or higher and 300° C. or lower, the following condition of Expression (A) is satisfied.

(1) a step of installing a transparent resin layer and a photosensitive black resin layer on a substrate in order

(2) a step of exposing the photosensitive black resin layer through a mask having a pattern and developing the exposed resin to form a laminate having a black pattern

Ra−Rb<0.5 Expression (A)

(In Expression (A), Rb represents a reflectance at a wavelength of 550 nm in a black patterned region of a laminate having a black pattern before the heat treatment, and Ra represents a reflectance at a wavelength of 550 nm in the black patterned region of the laminate having a black pattern after the heat treatment.)

In addition, examples of the method for manufacturing a carbon nano-tube include a method disclosed in JP2007-138109A.

JP2007-138109A discloses a method for manufacturing a carbon nano-tube dispersion product, in which a high molecular-weight compound is dissolved in an organic solvent to prepare a high molecular-weight compound solution having a viscosity of 20 to 30,000 cP, and a carbon nano-tube is added to and dispersed in the high molecular-weight compound solution.

Further, as a conventional display device, a display device disclosed in JP2014-209198A is known.

JP2014-209198A discloses a display device that includes a first substrate having a first surface and a second surface facing the first surface, a second substrate which is disposed to face the first substrate and has a first surface facing the second surface of the first substrate and a second surface facing the first surface, and a plurality of light emission parts provided on the second surface of the first substrate to be spaced apart from the second substrate. In the display device, a light transmission suppressing layer which includes a light transmission part for transmitting light from the light emission part and corresponds to each of the light emission parts is formed on the second surface of the second substrate, and an antireflection layer is formed in the light transmission part.

### SUMMARY OF THE INVENTION

An object to be achieved by one embodiment of the present invention is to provide a front member of an LED display, in which both diffuse reflectance and specular reflectance have low values.

In addition, another object to be achieved by another embodiment of the present invention is to provide a method for manufacturing a front member of an LED display, in which both diffuse reflectance and specular reflectance have low values.

Means for solving the above problems include the following aspects.

<1> A front member of an LED display, comprising a support and a colored layer containing an organic resin and a carbon nano-tube, in which an uneven shape is provided on a surface of the colored layer opposite to a side on which the support is provided.

<2> The front member of an LED display according to <1>, in which an average height of protrusions in the uneven shape is 150 nm to 1,000 nm.

<3> The front member of an LED display according to <1> or <2>, in which an average pitch of protrusions in the uneven shape is 50 nm to 500 nm.

<4> The front member of an LED display according to any one of <1> to <3>, in which an average thickness of the colored layer is 5 μm or more.

<5> The front member of an LED display according to any one of <1> to <4>, in which a content of the carbon nano-tube in the colored layer is 0.5% by mass to 10% by mass with respect to a total mass of the colored layer.

<6> The front member of an LED display according to any one of <1> to <5>, in which an average fiber diameter of the carbon nano-tube is 8 nm to 25 nm.

<7> The front member of an LED display according to any one of <1> to <6>, in which in the front member of an LED display, a specular reflectance of the colored layer is 1% or less and a diffuse reflectance of the colored layer is 0.5% or less on a side on which the uneven shape is provided.

<8> The front member of an LED display according to any one of <1> to <7>, in which in the front member of an LED display, a tint L value of the colored layer on a side on which the uneven shape is provided is 2 or less.

<9> The front member of an LED display according to any one of <1> to <8>, in which the colored layer contains a resin obtained by polymerizing an ethylenic unsaturated compound.

<10> The front member of an LED display according to any one of <1> to <9>, in which the front member of an LED display is used for removing stray light.

<11> A method for manufacturing a front member of an LED display, comprising a step of forming a photosensitive layer on a support using a photosensitive composition containing at least one compound selected from the group consisting of a binder polymer and an ethylenic unsaturated compound, and a carbon nano-tube, a step of forming an uneven shape on a surface of the photosensitive layer opposite to a side on which the support is provided, and a step of patterning the photosensitive layer.

<12> The method for manufacturing a front member of an LED display according to <11>, in which the step of forming an uneven shape is a step of pressing a stamper having a moth-eye structure against the surface of the photosensitive layer opposite to the side on which the support is provided, thereby forming an uneven shape.

According to one embodiment of the present invention, it is possible to provide a front member of an LED display, in which both diffuse reflectance and specular reflectance have low values.

In addition, according to another embodiment of the present invention, it is possible to provide a method for manufacturing a front member of an LED display, in which both diffuse reflectance and specular reflectance have low values.

### DESCRIPTION OF THE PREFERRED EMBODIMENTS

Hereinafter, the contents of the present disclosure will be described in detail. The description of the constitutional requirements described below is based on the representative embodiments of the present disclosure, but the present disclosure is not limited to such embodiments.

In the present disclosure, “to” indicating a numerical range is used to mean that numerical values described before and after “to” are included as a lower limit value and an upper limit value, respectively.

In the numerical ranges described stepwise in the present specification, the upper limit value or the lower limit value described in one numerical range may be replaced with the upper limit value or the lower limit value of the numerical range described stepwise in other stages. Further, in the numerical ranges described in the present specification, the upper limit value or the lower limit value of the numerical range may be replaced with the value shown in Examples.

In addition, in describing a group (atomic group) in the present disclosure, the description which does not indicate substituted or unsubstituted includes not only a group having no substituent but also a group having a substituent. For example, the “alkyl group” includes not only an alkyl group having no substituent (an unsubstituted alkyl group) but also an alkyl group having a substituent (a substituted alkyl group).

In the present specification, the term “total solid content” refers to the total mass of components excluding the solvent from the total composition content of the composition. In addition, the “solid content” refers to a component excluding the solvent as described above and may be, for example, a solid or a liquid at 25° C.

In the present disclosure, “% by mass” has the same meaning as “% by weight”, and “parts by mass” has the same meaning as “parts by weight”.

In the present disclosure, a combination of two or more preferred aspects is a more preferred aspect.

In the present disclosure, in a case where there are a plurality of substances corresponding to each component in the composition, the amount of each composition in the composition means the total amount of the plurality of substances present in the composition unless otherwise particularly specified.

In the present disclosure, the term “step” includes not only an independent step but also a step that cannot be clearly distinguished from other steps, as long as the intended purpose of the step is achieved.

In the present disclosure, “(meth)acrylic acid” has a concept that includes both acrylic acid and methacrylic acid, “(meth)acrylate” has a concept that includes both acrylate and methacrylate, and “(meth)acryloyl group” has a concept that includes both an acryloyl group and a methacryloyl group.

Unless otherwise specified, the weight-average molecular weight (Mw) and the number-average molecular weight (Mn) in the present disclosure are molecular weights converted using polystyrene as a standard substance, which are obtained by measuring with a gel permeation chromatography (GPC) analytical apparatus using TSKgel GMHxL, TSKgel G4000HxL, and TSKgel G2000HxL (trade names, all manufactured by TOSOH CORPORATION) as columns, tetrahydrofuran (THF) as a solvent, and a differential refractometer as a detector.

In the present disclosure, the proportion of the constitutional unit in the resin indicates a molar proportion unless otherwise specified.

In the present disclosure, the molecular weight in a case of having a molecular weight distribution indicates the weight-average molecular weight (Mw) unless otherwise specified.

Hereinafter, the present disclosure will be described in detail.

(Front Member of LED Display)

A front member of a light emitting diode (LED) display according to the present disclosure includes a support and a colored layer containing an organic resin and a carbon nano-tube, and in the front member of an LED display, an uneven shape is provided on the surface of the colored layer opposite to the side on which the support is provided.

Further, the front member of a LED display according to the present disclosure can be suitably used as a front member of a micro LED (μ-LED) display.

The size (maximum diameter) of an LED in the micro LED display is preferably less than 100 μm.

The front member is a member provided on the display side of the LED display.

Further, the front member of a LED display according to the present disclosure is preferably a front member for removing stray light of an LED display.

As a conventional front member of an LED display, for example, a front member having a black layer containing carbon black has been known. However, the front member having the black layer has had high values of both diffuse reflectance (SCE reflectance) and specular reflectance (SCI reflectance), and the visibility of the displayed contents has been inferior.

As a result of diligent studies, the inventors of the present invention have found that it is possible to provide a front member of an LED display, in which both diffuse reflectance and specular reflectance have low values, by adopting the configurations described above.

The mechanism of the action of excellent effects due to these configurations is not clear, but it is presumed as follows.

Since a colored layer containing a carbon nano-tube and having an uneven shape on the surface is included, the carbon nano-tube absorbs the diffusely reflected light of the incident light, thereby suppressing diffuse reflectance, and since the carbon nano-tube is included and the surface has the uneven shape, the regular reflection of the incident light can be suppressed and absorbed, thereby suppressing the specular reflectance.

Since the front member of an LED display according to the present disclosure can suppress both regular reflection and diffuse reflection, an LED display having the front member of an LED display according to the present disclosure can display a sharp black image with less reflected glare and less stray light, and thus the visibility of the displayed contents is excellent.

Examples of the front member of an LED display include a front member used in the LED display described in paragraphs 0032 to 0038 of JP2014-209198A. In this example, the light transmission suppressing layer 31 and the second substrate 12 respectively correspond to the colored layer and the support in the present disclosure. In addition, examples of the LED display are exemplified in paragraphs 0039 to 0042 of JP2014-209198A. In this example, the light non-transmission layer 34 and the light transmission part 35 respectively correspond to the colored layer and the support in the present disclosure.

Hereinafter, the front member of an LED display according to the present disclosure will be described in detail.

<Colored Layer>

The front member of an LED display according to the present disclosure has a colored layer containing an organic resin and a carbon nano-tube, in which an uneven shape is provided on the surface of the colored layer opposite to the side on which the support is provided.

The colored layer is preferably a layer obtained by curing a photosensitive composition and more preferably a layer obtained by curing a negative type photosensitive composition. In a case where the colored layer is formed from the photosensitive composition, the colored layer can be easily formed in any pattern shape.

<<Uneven Shape>>

The colored layer has an uneven shape on the surface of the colored layer opposite to a side on which the support is provided.

The uneven shape may be provided only on a part of the surface of the colored layer, but it is preferably provided on the entire surface from the viewpoint of further exhibiting the effects in the present disclosure.

The shape of unevenness itself in the uneven shape is not particularly limited and may be any desired shape. Examples thereof include a prismatic shape, a cylinder shape, a pyramid shape, a cone shape, a truncated pyramid shape, a truncated cone shape, and an indefinite shape.

Further, the shapes of the unevenness in the uneven shape may be the same or different (a similar shape, a random shape, or the like).

For example, in a case where the uneven shape is formed by using a stamper having a moth-eye structure described later, uneven shapes having the same shape of unevenness itself can be easily formed, and in a case where an ion beam described later is used to form the uneven shape, the uneven shape has a random shape of unevenness.

The average height of protrusions in the uneven shape is preferably 10 nm to 1,500 nm, more preferably 50 nm to 1,200 nm, still more preferably 150 nm to 1,000 nm, and particularly preferably 150 nm to 500 nm, from the viewpoint of suppressing specular reflectance.

In addition, the average pitch of the protrusions in the uneven shape is preferably 10 nm to 1,500 nm, more preferably 50 nm to 500 nm, still more preferably 75 nm to 400 nm, and particularly preferably 100 nm to 300 nm, from the viewpoint of suppressing specular reflectance.

The average pitch of the protrusions in the uneven shape is an average distance between the protrusions, and more specifically, an average distance (not including the distance in the thickness direction) on the plane between the central portions of the protrusions.

The average height and the average pitch of the protrusions in the uneven shape are measured by the following method.

The colored layer is cut perpendicularly in the thickness direction, the cross section is observed with a scanning electron microscope, and the height of the protrusions and the pitch of the protrusions are measured. These measurements are repeated to measure the heights of at least 100 protrusions and the pitches of at least 100 protrusions, each average value thereof is obtained, and the average height and the average pitch of the protrusions in the uneven shape are calculated. The height of the protrusions in the uneven shape is a height measured from the deepest bottom surface of the cross section, with which the uneven shape is in contact.

<<Average Thickness>>

The average thickness of the colored layer is preferably 1 μm or more, more preferably 5 μm or more, still more preferably 5 μm or more and 100 μm or less, and particularly preferably 7 μm or more and 50 μm or less, from the viewpoint of suppressing specular reflectance and diffuse reflectance and saving space.

The average thickness of the colored layer is obtained by cutting a cross section of the colored layer in a direction perpendicular to the thickness direction, measuring the thickness of the colored layer at 10 or more points with an optical microscope or a scanning electron microscope to obtain an average value thereof, and calculating the average thickness of the colored layer.

In addition, along with measuring the average height and the average pitch of the protrusions in the uneven shape, the cross section of the colored layer cut in the direction perpendicular to the thickness direction can be observed with a scanning electron microscope to measure the thickness of the colored layer.

<<Carbon Nano-Tube>>

The colored layer contains a carbon nano-tube.

The carbon nano-tube used in the present disclosure is not particularly limited, and a conventionally known carbon nano-tube can be used.

A carbon nano-tube (CNT) has a shape in which a graphene (a 6-membered ring network) sheet is wound in a tubular shape, and the diameter thereof is preferably, for example, several nanometers to 100 nm, and the length thereof is preferably, for example, several nanometers to several micrometers.

In addition, the carbon nano-tube may have a 5-membered ring structure or a 7-membered ring structure in a part thereof as well as the 6-membered ring structure which is a graphene structure.

The carbon nano-tube used in the present disclosure is not limited as long as at least a part thereof is tubular and includes one in which the tube is blocked (a carbon nano-horn).

A carbon nano-tube is preferably used for the colored layer in the present disclosure since the carbon nano-tube is very regular, has a high aspect ratio, and has high mechanical strength and high thermal conductivity.

Currently, carbon nano-tube is easily synthesized in the quantity of grams.

The carbon nano-tube is basically a single layer of a graphene that is wound in a tubular shape, and examples thereof include a multi wall nano-tube (Multi Wall Carbon Nano-Tube: MWCNT) in which a graphene sheet is wound to form several concentric walls, and a single wall nano-tube (Single Wall Carbon Nano-Tube: SWCNT).

SWCNT consist of a single layer of a graphene sheet bonded in a hexagonal shape (graphite is formed by stacking graphene sheets in a pancake shape).

The carbon nano-tube has a large surface area, and for example, the size thereof reaches 1,000 m²/g in the closed state and 2,000 m²/g in the open state in many cases.

The inventors of the present inventions speculate that the number of times of the light absorption in the colored layer increases due to the tube shape of the carbon nano-tube and the size of the surface area, and thus it is possible to effectively suppress specular reflectance and diffuse reflectance, particularly diffuse reflectance.

Furthermore, in the carbon nano-tube, a hexagonal orientation of graphene can take various directions with respect to the axis of the tube. The spiral structure generated due to the various directions is called chiral and a two-dimensional lattice vector from a reference point of a 6-membered ring on the graphene is called a chiral vector (CO. The chiral vector is represented as follows, by using two primitive translation vectors of the two-dimensional hexagonal lattice, a¹ and a².

Cₕ=na¹+ma²

The set (n, m) of two integers is called the chiral index and is used to represent the structure of the nano-tube. The diameter and spiral angle of the tube in the carbon nano-tube is determined according to the chiral index.

In addition, the three-dimensional structure of the carbon nano-tube depends on the chiral index. In a case of n=m, the three-dimensional structure has a tubular carbon atom arrangement structure called an armchair type, which exhibits metallicity, in a case of m=0, the three-dimensional structure has a tubular carbon atom arrangement structure called a zigzag type, and in a case other than the above cases, the three-dimensional structure has a general tube structure having a spiral structure called a chiral type. Further, in a case where the value of (n−m) is a multiple of 3, the carbon nano-tube exhibits metallicity (a metal-type carbon nano-tube), and in a case where the value of (n−m) is a value other than the multiple of 3, the carbon nano-tube exhibits semiconductor characteristics (a semiconductor-type carbon nano-tube).

In the present disclosure, any carbon nano-tube having a structure of any chiral index can be suitably used.

The carbon nano-tube used in the present disclosure may be a single wall carbon nano-tube or a multi wall carbon nano-tube, but it is preferably a single wall carbon nano-tube from the viewpoint of suppressing specular reflectance (SCI reflectance) and diffuse reflectance (SCE reflectance).

In addition, the carbon nano-tube used in the present disclosure may be a semiconductor-type carbon nano-tube or a metal-type carbon nano-tube, but it is preferably a semiconductor-type carbon nano-tube from the viewpoint of the dispersion stability in the dispersion liquid described later and the dispersibility in the colored layer.

The average fiber diameter of the carbon nano-tube is preferably 1 nm to 100 nm, more preferably 5 nm to 50 nm, and particularly preferably 8 nm to 25 nm, from the viewpoint of suppressing specular reflectance (SCI reflectance) and diffuse reflectance (SCE reflectance).

The average fiber diameter of the carbon nano-tube is measured by the following method.

A cross section of the colored layer or an isolated carbon nano-tube is observed with a scanning transmission electron microscope (manufactured by JEOL Ltd.). The average fiber diameter (nm) of the carbon nano-tube is calculated by randomly selecting 100 carbon nano-tubes in the observation photograph, measuring the outer diameter of each thereof, and obtaining the number-average value thereof.

The colored layer may contain one type of carbon nano-tube alone or may contain two or more types of carbon nano-tubes.

From the viewpoint of suppressing specular reflectance and diffuse reflectance, the content of the carbon nano-tube in the colored layer is preferably 0.1% by mass to 20% by mass, more preferably 0.5% by mass to 10% by mass, still more preferably 1% by mass to 5% by mass, and particularly preferably 1.5% by mass to 4% by mass, with respect to the total mass of the colored layer.

<<Dispersant>>

The colored layer preferably contains a dispersant from the viewpoint of suppressing specular reflectance and diffuse reflectance.

Preferred examples of the dispersant include a polymer dispersant. The polymer dispersant may also function as a binder polymer described later.

Examples of the polymer dispersant include an acrylic polymer, a styrene-based polymer, an epoxy-based polymer, an amide-based polymer, an amide epoxy-based polymer, an alkyd-based polymer, a phenol-based polymer, and a cellulose-based polymer.

The polymer dispersant is preferably an alkali-soluble resin and more preferably a polymer having a carboxy group.

Among these, the polymer dispersant is preferably an acrylic polymer, an epoxy-based polymer, or a cellulose-based polymer, more preferably an acrylic polymer, and particularly preferably a (meth)acrylic acid copolymer, from the viewpoint of the dispersibility and the suppression of specular reflectance and diffuse reflectance.

The acrylic polymer can be produced, for example, by polymerizing a (meth)acrylic compound.

Examples of the polymerizable monomer include polymerizable styrene derivatives such as styrene, vinyltoluene, α-methylstyrene, p-methylstyrene, and p-ethylstyrene; esters of vinyl alcohols such as acrylamide, acrylonitrile, and vinyl-n-butyl ether, a (meth)acrylic acid alkyl ester, a (meth)acrylic acid tetrahydrofurfuryl ester, a (meth)acrylic acid dimethylaminoethyl ester, a (meth)acrylic acid diethylaminoethyl ester, a (meth)acrylic acid glycidyl ester, 2,2,2-trifluoroethyl (meth)acrylate, 2,2,3,3-tetrafluoropropyl (meth)acrylate, (meth)acrylic acid, α-bromo(meth)acrylic acid, α-chloro(meth)acrylic acid, β-frill(meth)acrylic acid, β-styryl(meth)acrylic acid, maleic acid, maleic acid anhydride, maleic acid monoesters such as monomethyl maleate, monoethyl maleate, and monoisopropyl maleate, fumaric acid, cinnamic acid, α-cyanocinnamic acid, itaconic acid, crotonic acid, and propiolic acid.

Examples of the (meth)acrylic acid alkyl ester include methyl (meth)acrylate, ethyl (meth)acrylate, propyl (meth)acrylate, butyl (meth)acrylate, pentyl (meth)acrylate, hexyl (meth)acrylate, heptyl (meth)acrylate, octyl (meth)acrylate, 2-ethylhexyl (meth)acrylate, and structural isomers thereof.

The acid value of the polymer dispersant is preferably 30 mgKOH/g to 200 mgKOH/g and more preferably 45 mgKOH/g to 150 mgKOH/g.

The weight-average molecular weight of the polymer dispersant is preferably 1,000 to 1,000,000 and more preferably 4,000 to 200,000.

The colored layer may contain one type of the dispersant alone or may contain two or more types of the dispersants.

The content of the dispersant in the colored layer is not particularly limited, but it is preferably 0.05% by mass to 15% by mass with respect to the total mass of the colored layer.

In a case of forming the colored layer, it is preferable that a carbon nano-tube is dispersed to prepare a carbon nano-tube dispersion product, and the obtained carbon nano-tube dispersion product is used to prepare a photosensitive composition described later, thereby forming the colored layer.

The carbon nano-tube dispersion product preferably contains a carbon nano-tube and a dispersant, and more preferably contains a carbon nano-tube, a dispersant, and an organic solvent.

In a case where the viscosity is required to be lowered for applying the obtained dispersion product, the dispersion product can be diluted with an organic solvent. Alternatively, a polymer can be added to further increase the viscosity, whereby the viscosity can be adjusted to an appropriate level depending on the purpose of use.

The organic solvent that can be used for preparing the dispersion product is not particularly limited, and methanol, ethanol, acetone, methyl ethyl ketone, cyclohexanone, methyl cellosolve, ethyl cellosolve, toluene, N,N-dimethylformamide, propylene glycol monomethyl ether, or the like, or a mixture of these solvents can be preferably used.

The organic solvent may be used alone or in a combination of two or more thereof.

The content of the carbon nano-tube in the carbon nano-tube dispersion product is not particularly limited and may be appropriately adjusted depending on the dispersed state and the desired concentration.

In a case of adding the carbon nano-tube, it is preferable to apply a sufficient shearing force at the time of dispersion since a good dispersion product is obtained by dispersing the carbon nano-tube while loosening agglomerates and preventing re-aggregation.

The dispersion of the carbon nano-tube may be carried out while setting the filling level of the carbon nano-tube or may be carried out while monitoring the solution with an optical microscope to check the aggregation.

A device that can be used for dispersing the carbon nano-tube is particularly preferably a device using an ultrasonic mixing technology or a high shear mixing technology, and the dispersion product can be obtained by emulsification and dispersion with a dispersion means, for example, a stirrer, a homogenizer, a colloid mill, a flow jet mixer, a dissolver, a Manton emulsifying device, or ultrasonic device. In addition, the dispersion can be performed by processing with a conventionally known pulverizing means, for example, ball milling (with a ball mill, a vibration ball mill, a planetary ball mill, or the like), sand milling, colloid milling, jet milling, roller milling, or the like. In addition, a disperser device such as a vertical or horizontal agitator mill, an attritor, a colloid mill, a ball mill, a three-roll mill, a pearl mill, super mill, an impeller, a disperser, a KD mill, a dynatron, or a pressurized kneader, which is used for dispersing pigment, can be also used.

<<Organic Resin>>

The colored layer contains an organic resin.

The organic resin is preferably a resin obtained by curing a photosensitive composition and more preferably a resin obtained by curing a negative type photosensitive composition from the viewpoint of pattern formation properties.

In addition, the organic resin preferably contains a resin obtained by polymerizing a polymerizable compound and more preferably contains a resin obtained by polymerizing an ethylenic unsaturated compound, from the viewpoint of the pattern formation properties and the strength of the colored layer.

Further, the organic resin preferably contains a binder polymer and more preferably contains an alkali-soluble resin, from the viewpoint of the strength of the colored layer and the formation properties of the colored layer.

The colored layer is preferably a layer obtained by curing a photosensitive composition (preferably, a negative type photosensitive composition) containing components described below in addition to the carbon nano-tube.

In addition, the organic resin preferably contains a resin obtained by polymerizing an ethylenic unsaturated compound and more preferably contains a resin obtained by polymerizing an ethylenic unsaturated compound and the binder polymer described later.

<<Photosensitive Composition>>

The composition of the photosensitive composition that can be suitably used for forming the colored layer will be described in detail.

From the viewpoint of suppressing specular reflectance and diffuse reflectance, the content of the carbon nano-tube in the photosensitive composition is preferably 0.1% by mass to 20% by mass, more preferably 0.5% by mass to 10% by mass, still more preferably 1% by mass to 5% by mass, and particularly preferably 1.5% by mass to 4% by mass, with respect to the total solid content of the photosensitive composition.

In addition, the content of the dispersant in the photosensitive composition is not particularly limited, but it is preferably 0.05% by mass to 15% by mass with respect to the total solid content of the photosensitive composition.

In addition, in a case where each of the components of the photosensitive composition described later is contained as it is after the curing of the colored layer, the preferred content of each of the components in the colored layer is the same as the preferred content in the photosensitive composition described later, except that the basis of content is changed from the total solid content of the photosensitive composition to the total mass of the colored layer.

Ethylenic Unsaturated Compound

The photosensitive composition preferably contains an ethylenic unsaturated compound.

The ethylenic unsaturated compound is a component that contributes to photosensitivity (that is, photocuring properties) and strength of the obtained cured film.

The ethylenic unsaturated compound is a compound having one or more ethylenic unsaturated groups.

The photosensitive composition preferably contains, as an ethylenic unsaturated compound, a bifunctional or higher functional ethylenic unsaturated compound.

Here, the bifunctional or higher functional ethylenic unsaturated compound means a compound having two or more ethylenic unsaturated groups in one molecule thereof.

The ethylenic unsaturated group is preferably a (meth)acryloyl group.

The ethylenic unsaturated compound is preferably a (meth)acrylate compound.

From the viewpoint of the curability after curing, the photosensitive composition preferably contains a trifunctional or higher functional ethylenic unsaturated compound (preferably, a trifunctional or higher functional (meth)acrylate compound) and particularly preferably contains a bifunctional ethylenic unsaturated compound (preferably, a bifunctional (meth)acrylate compound) and a trifunctional or higher functional ethylenic unsaturated compound (preferably, a trifunctional or higher functional (meth)acrylate compound).

The bifunctional ethylenic unsaturated compound is not particularly limited and may be appropriately selected from conventionally known compounds.

Examples of the bifunctional ethylenic unsaturated compound include tricyclodecanedimethanol di(meth)acrylate, tricyclodecanedimethanol di(meth)acrylate, 1,9-nonanediol di(meth)acrylate, and 1,6-hexanediol di(meth)acrylate.

More specific examples of the bifunctional ethylenic unsaturated compound include tricyclodecanedimethanol diacrylate (A-DCP, manufactured by SHIN-NAKAMURA CHEMICAL CO., LTD.), tricyclodecanedimethanol di(meth)acrylate (DCP, manufactured by SHIN-NAKAMURA CHEMICAL CO., LTD.), 1,9-nonanediol diacrylate (A-NOD-N, manufactured by SHIN-NAKAMURA CHEMICAL CO., LTD.), and 1,6-hexanediol diacrylate (A-HD-N, manufactured by SHIN-NAKAMURA CHEMICAL CO., LTD.).

The trifunctional or higher functional ethylenic unsaturated compound is not particularly limited and may be appropriately selected from conventionally known compounds.

Examples of the trifunctional or higher functional ethylenic unsaturated compound include dipentaerythritol (tri/tetra/penta/hexa)(meth)acrylate, pentaerythritol (tri/tetra)(meth)acrylate, trimethylolpropane tri(m eth)acrylate, ditrimethylolpropane tetra(meth)acrylate, isocyanuric acid(meth)acrylate, and a(meth)acrylate compound having a glyceryl tri(meth)acrylate skeleton.

Here, “(tri/tetra/penta/hexa)(meth)acrylate” has a concept including tri(meth)acrylate, tetra(meth)acrylate, penta(meth)acrylate, and hexa(meth)acrylate, and “(tri/tetra)(meth)acrylate” has a concept that includes tri(meth)acrylate and tetra(meth)acrylate.

Examples of the ethylenic unsaturated compound include a caprolactone-modified compound of a (meth)acrylate compound (KAYARAD (registered trade mark) DPCA-20, manufactured by Nippon Kayaku Co., Ltd., A-9300-1CL manufactured by SHIN-NAKAMURA CHEMICAL CO., LTD., or the like), an alkylene oxide-modified compound of a (meth)acrylate compound (KAYARAD RP-1040 manufactured by Nippon Kayaku Co., Ltd., ATM-35E or A-9300 manufactured by SHIN-NAKAMURA CHEMICAL CO., LTD., EBECRYL (registered trade mark) 135 manufactured by DAICEL-ALLNEX LTD.), an ethoxylated glyceryl triacrylate (A-GLY-9E, manufactured by SHIN-NAKAMURA CHEMICAL CO., LTD.), and the like.

Examples of the ethylenic unsaturated compound include a urethane (meth)acrylate compound (preferably, a trifunctional or higher functional urethane (meth)acrylate compound).

Examples of the trifunctional or higher functional urethane (meth)acrylate compound include 8UX-015A (manufactured by TAISEI FINE CHEMICAL CO., LTD.), UA-32P (manufactured by SHIN-NAKAMURA CHEMICAL CO., LTD.), and UA-1100H (manufactured by SHIN-NAKAMURA CHEMICAL CO., LTD.), and the like.

In addition, from the viewpoint of improving the developability, the ethylenic unsaturated compound preferably contains an ethylenic unsaturated compound having an acid group.

Examples of the acid group include a phosphoric acid group, a sulfonic acid group, and a carboxy group, and a carboxy group is preferable.

Examples of the ethylenic unsaturated compound having an acid group include a trifunctional or tetrafunctional ethylenic unsaturated compound (a compound (acid value=80 mgKOH/g to 120 mgKOH/g) obtained by introducing a carboxy group into pentaerythritol tri- and tetra-acrylate (PETA) skeleton) having an acid group, a pentafunctional or hexafunctional ethylenic unsaturated compound (a compound (acid value=25 mgKOH/g to 70 mgKOH/g) obtained by introducing a carboxy group into dipentaerythritol penta- and hexa-acrylate (DPHA) skeleton) having an acid group, and the like.

This trifunctional or higher functional ethylenic unsaturated compound having an acid group may be used in combination with a bifunctional ethylenic unsaturated compound having an acid group, as necessary.

The ethylenic unsaturated compound having an acid group is preferably at least one selected from the group consisting of a bifunctional or higher functional ethylenic unsaturated compound containing a carboxy group and a carboxylic acid anhydride thereof. Such a compound enhances the developability and the strength of the cured film.

The bifunctional or higher functional ethylenic unsaturated compound containing a carboxy group is not particularly limited and can be appropriately selected from conventionally known compounds.

As the bifunctional or higher functional ethylenic unsaturated compound containing a carboxy group, for example, ARONIX (registered trade mark) TO-2349 (manufactured by TOAGOSEI CO., LTD.), ARONIX M-520 (manufactured by TOAGOSEI CO., LTD.), or ARONIX M-510 (manufactured by TOAGOSEI CO., LTD.) can be preferably used.

In addition, the ethylenic unsaturated compound having an acid group is preferably a polymerizable compound having an acid group, which is described in paragraphs 0025 to 0030 of JP2004-239942A. The contents of this patent publication are incorporated in the present specification by reference.

The weight-average molecular weight (Mw) of the ethylenic unsaturated compound used in the present disclosure is preferably 200 to 3,000, more preferably 250 to 2,600, still more preferably 280 to 2,200, and particularly preferably 300 to 2,200.

Further, among the ethylenic unsaturated compounds used in the photosensitive composition described above, the proportion of the content of the ethylenic unsaturated compound having a molecular weight of 300 or less is preferably 30% by mass or less, more preferably 25% by mass or less, and still more preferably 20% by mass or less, with respect to all of the ethylenic unsaturated compounds contained in the photosensitive composition.

The ethylenic unsaturated compound may be used alone or in a combination of two or more thereof.

The content of the ethylenic unsaturated compound is preferably 1% by mass to 70% by mass, more preferably 10% by mass to 70% by mass, still more preferably 20% by mass to 60% by mass, and particularly preferably 20% by mass to 50% by mass, with respect to the total solid content of the photosensitive composition.

In addition, in a case where the photosensitive composition contains an ethylenic unsaturated compound (preferably, a bifunctional or higher functional ethylenic unsaturated compound containing a carboxy group or a carboxylic acid anhydride thereof) having an acid group, the content of the ethylenic unsaturated compound having an acid group is preferably 1% by mass to 50% by mass, more preferably 1% by mass to 20% by mass, and still more preferably 1% by mass to 10% by mass, with respect to the total solid content of the photosensitive composition.

Photopolymerization Initiator

The photosensitive composition preferably contains a photopolymerization initiator.

The photopolymerization initiator is not particularly limited, and a conventionally known photopolymerization initiator can be used.

Examples of the photopolymerization initiator include a photopolymerization initiator having an oxime ester structure (hereinafter, also referred to as an “oxime-based photopolymerization initiator”), a photopolymerization initiator having an α-aminoalkyl phenone structure (hereinafter, also referred to as an “α-aminoalkyl phenone-based photopolymerization initiator”), a photopolymerization initiator having an α-hydroxyalkyl phenone structure (hereinafter, also referred to as an “α-hydroxyalkyl phenone-based polymerization initiator”), a photopolymerization initiator having an acylphosphine oxide structure (hereinafter, also referred to as an “acylphosphine oxide-based photopolymerization initiator”), and a photopolymerization initiator having an N-phenylglycine structure (hereinafter, also referred to as an “N-phenylglycine-based photopolymerization initiator”).

The photopolymerization initiator preferably includes at least one selected from the group consisting of an oxime-based photopolymerization initiator, an α-aminoalkyl phenone-based photopolymerization initiator, an α-hydroxyalkyl phenone-based polymerization initiator, and an N-phenylglycine-based photopolymerization initiator, and more preferably includes at least one selected from the group consisting of an oxime-based photopolymerization initiator, an α-aminoalkyl phenone-based photopolymerization initiator, and an N-phenylglycine-based photopolymerization initiator.

In addition, examples of the photopolymerization initiator which may be used include polymerization initiators described in paragraphs 0031 to 0042 of JP2011-095716A and paragraphs 0064 to 0081 of JP2015-014783A.

Examples of the commercially available photopolymerization initiator include 1-[4-(phenylthio)]-1,2-octanedione-2-(O-benzoyloxime) (trade name: IRGACURE (registered trade mark) OXE-01, manufactured by BASF SE), 1-[9-ethyl-6-(2-methylbenzoyl)-9H-carb azole-3-yl]etanone-1-(O-acetyloxime) (trade name: IRGACURE OXE-02, manufactured by BASF SE), 2-(dimethylamino)-2-[(4-methylphenyl)methyl]-1-[4-(4-morpholinyl)phenyl]-1-butanone (trade name: IRGACURE 379EG, manufactured by BASF SE), 2-methyl-1-(4-methylthiophenyl)-2-morpholinopropane-1-one (trade name: IRGACURE 907, manufactured by BASF SE), 2-hydroxy-1-{4-[4-(2-hydroxy-2-methyl-propionyl)benzyl]phenyl}-2-methyl propan-1-one (trade name: IRGACURE 127, manufactured by BASF SE), 2-benzyl-2-dimethylamino-1-(4-morpholinophenyl)butanone-1 (trade name): IRGACURE 369, manufactured by BASF SE), 2-hydroxy-2-methyl-1-phenylpropan-1-one (trade name: IRGACURE 1173, manufactured by BASF SE), 1-hydroxycyclohexylphenylketone (trade name: IRGACURE 184, manufactured by BASF SE), 2,2-dimethoxy-1,2-diphenylethane-1-one (trade name: IRGACURE 651, manufactured by BASF SE), and an oxime ester-based photopolymerization initiator (trade name: Lunar 6, manufactured by DKSH Management Ltd.)

The photopolymerization initiator may be used alone or in a combination of two or more thereof.

The content of the photopolymerization initiator is not particularly limited, but it is preferably 0.1% by mass or more, more preferably 0.5% by mass or more, and still more preferably 1.0% by mass or more, with respect to the total solid content of the photosensitive composition.

In addition, the content of the photopolymerization initiator is preferably 10% by mass or less and more preferably 5% by mass or less, with respect to the total solid content of the photosensitive composition.

Binder Polymer

The photosensitive composition preferably contains a binder polymer.

The binder polymer is preferably an alkali-soluble resin.

The acid value of the binder polymer is not particularly limited, but from the viewpoint of developability, the binder polymer is preferably a binder polymer having an acid value of 60 mgKOH/g or more, more preferably an alkali-soluble resin having an acid value of 60 mgKOH/g or more, and particularly preferably a carboxy group-containing acrylic resin having an acid value of 60 mgKOH/g or more.

It is presumed in a case where the binder polymer has an acid value, the binder polymer is thermally crosslinked with a compound capable of reacting with an acid by heating, whereby the three-dimensional crosslink density can be increased. In addition, it is presumed that the carboxy group of the carboxy group-containing acrylic resin is dehydrated and thus becomes hydrophobic, which contributes to the improvement of the resistance against moisture and heat.

The carboxy group-containing acrylic resin having an acid value of 60 mgKOH/g or more (hereinafter, may be referred to as a specific polymer A) is not particularly limited as long as the above acid value conditions are satisfied, and can be appropriately selected from conventionally known resins and used.

For example, a binder polymer which is a carboxy group-containing acrylic resin having an acid value of 60 mgKOH/g or more among the polymers described in paragraph 0025 of JP2011-095716A, a carboxy group-containing acrylic resin having an acid value of 60 mgKOH/g or more among the polymers described in paragraphs 0033 to 0052 of JP2010-237589A, or the like can be preferably used as the specific polymer A in the present embodiment.

Here, the (meth)acrylic resin refers to a resin containing at least one of a constitutional unit derived from (meth)acrylic acid or a constitutional unit derived from a (meth)acrylic acid ester.

The total proportion of the constitutional unit derived from (meth)acrylic acid and the constitutional unit derived from a (meth)acrylic acid ester in the (meth)acrylic resin is preferably 30% by mole or more and more preferably 50% by mole or more.

The preferred range of the copolymerization ratio of the monomer having a carboxy group in the specific polymer A is 5% by mass to 50% by mass, more preferably 5% by mass to 40% by mass, and still more preferably 20% by mass to 30% by mass, with respect to 100% by mass of the specific polymer A.

The specific polymer A may have a reactive group, and examples of the means for introducing the reactive group into the specific polymer A include a method of reacting an epoxy compound, a blocked isocyanate, an isocyanate, a vinyl sulfone compound, an aldehyde compound, a methylol compound, a carboxylic acid anhydride, or the like with a hydroxyl group, a carboxy group, a primary amino group, a secondary amino group, an acetoacetyl group, a sulfonic acid group, or the like.

Among these, the reactive group is preferably a radically polymerizable group, more preferably an ethylenic unsaturated group, and particularly preferably a (meth)acryloxy group.

Further, the binder polymer, particularly the specific polymer A preferably has a constitutional unit having an aromatic ring from the viewpoint of moisture permeability and strength after curing.

Examples of the monomer forming a constitutional unit having an aromatic ring include styrene, tert-butoxystyrene, methyl styrene, α-methyl styrene, and benzyl (meth)acrylate.

The constitutional unit having an aromatic ring preferably contains at least one constitutional unit represented by Formula P-2 described later. Further, the constitutional unit having an aromatic ring is preferably a constitutional unit derived from a styrene compound.

In a case where the binder polymer contains a constitutional unit having an aromatic ring, the content of the constitutional unit having an aromatic ring is preferably 5% by mass to 90% by mass, preferably 10% by mass to 70% by mass, and still more preferably 20% by mass to 50% by mass, with respect to the total mass of the binder polymer.

Further, the binder polymer, particularly the specific polymer A preferably has a constitutional unit having an aliphatic cyclic skeleton from the viewpoint of tackiness and the strength after curing.

Specific examples of the monomer forming a constitutional unit having an aliphatic cyclic skeleton include dicyclopentanyl (meth)acrylate, cyclohexyl (meth)acrylate, and isobornyl (meth)acrylate.

Preferred examples of the aliphatic ring contained in the constitutional unit having the aliphatic cyclic skeleton include a dicyclopentane ring, a cyclohexane ring, an isoborone ring, and a tricyclodecane ring. Among them, a tricyclodecane ring is particularly preferable.

In a case where the binder polymer contains a constitutional unit having an aliphatic cyclic skeleton, the content of the constitutional unit having an aliphatic cyclic skeleton is preferably 5% by mass to 90% by mass and preferably 10% by mass to 80% by mass, with respect to the total mass of the binder polymer.

Further, the binder polymer, particularly the specific polymer A preferably has a constitutional unit having an ethylenic unsaturated group and more preferably a constitutional unit having an ethylenic unsaturated group in a side chain, from the viewpoint of tackiness and the strength after curing.

In the present disclosure, the “main chain” indicates the relatively longest bonding chain in the molecule of the high molecular-weight compound that constitutes the resin, and the “side chain” indicates an atomic group branched from the main chain.

The ethylenic unsaturated group is preferably a (meth)acryloyl group and more preferably a (meth)acryloxy group.

In a case where the binder polymer contains a constitutional unit having an ethylenic unsaturated group, the content of the constitutional unit having an ethylenic unsaturated group is preferably 5% by mass to 70% by mass, preferably 10% by mass to 50% by mass, and still more preferably 20% by mass to 40% by mass, with respect to the total mass of the binder polymer.

The specific polymer A is preferably a compound A shown below. The content rate of each constitutional unit shown below can be appropriately changed depending on the purpose.

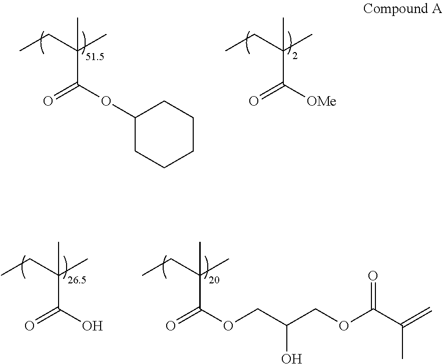

The acid value of the binder polymer used in the present disclosure is preferably 60 mgKOH/g or more, more preferably 60 mgKOH/g to 200 mgKOH/g, still more preferably 60 mgKOH/g to 150 mgKOH/g, and particularly preferably 60 mgKOH/g to 110 mgKOH/g.

In the present specification, the acid value means a value measured according to the method described in JIS K0070 (1992).

In a case where the binder polymer contains a binder polymer having an acid value of 60 mgKOH/g or more, in addition to the advantages described above, a secondary resin layer to be described later contains an acrylic resin having an acid group, which can enhance the interlaminar adhesion between the photosensitive layer and the secondary resin layer.

The weight-average molecular weight of the specific polymer A is preferably 10,000 or more and more preferably 20,000 to 100,000.

In addition to the specific polymer described above, any film-forming resin can be appropriately selected and used as the binder polymer depending on the purpose. From the viewpoint of using a transfer film as an electrode protective film of a capacitance type input device, a film-forming resin having good surface hardness and good heat resistance is preferable, and an alkali-soluble resin is more preferable. Among the alkali-soluble resins, a conventionally known photosensitive siloxane resin material or the like can be preferably mentioned.

The binder polymer used in the present disclosure preferably includes a polymer containing a constitutional unit having a carboxylic acid anhydride structure (hereinafter, also referred to as a specific polymer B). In a case where the specific polymer B is included, developability and the strength after curing are more excellent.

The carboxylic acid anhydride structure may be any one of a chain-like carboxylic acid anhydride structure or a cyclic carboxylic acid anhydride structure, but a cyclic carboxylic acid anhydride structure is preferable.

The ring of the cyclic carboxylic acid anhydride structure is preferably a 5- to 7-membered ring, more preferably a 5-membered ring or a 6-membered ring, and still more preferably a 5-membered ring.

In addition, the cyclic carboxylic acid anhydride structure may be condensed or bonded to another ring structure to form a polycyclic structure, but it is preferable that a polycyclic structure is not formed.

In a case where another ring structure is condensed or bonded to the cyclic carboxylic acid anhydride structure to form a polycyclic structure, the polycyclic structure is preferably a bicyclo structure or a spiro structure.

In the polycyclic structure, the number of the above another ring structure condensed or bonded to the cyclic carboxylic acid anhydride structure is preferably 1 to 5 and more preferably 1 to 3.

Examples of the above another ring structure include a cyclic hydrocarbon group having 3 to 20 carbon atoms and a heterocyclic group having 3 to 20 carbon atoms.

The heterocyclic group is not particularly limited, and examples thereof include an aliphatic heterocyclic group and an aromatic heterocyclic group.

In addition, the heterocyclic group is preferably a 5-membered ring or a 6-membered ring and particularly preferably a 5-membered ring.

Further, the heterocyclic group is preferably a heterocyclic group containing at least one oxygen atom (for example, an oxolane ring, an oxane ring, or a dioxane ring).

The constitutional unit having a carboxylic acid anhydride structure is preferably a constitutional unit containing a divalent group obtained by removing two hydrogen atoms from a compound represented by Formula P-1 in the main chain, or a constitutional unit in which a monovalent group obtained by removing one hydrogen atom from the compound represented by Formula P-1 is bonded to the main chain directly or through a divalent linking group.

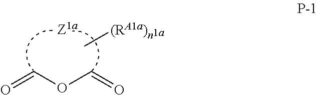

In Formula P-1, R^{A1a} represents a substituent, and n^{1a} pieces of R^{A1a}'s may be the same or different from each other.

Z^{1a} represents a divalent group that forms a ring containing —C(═O)—O—C(═O)—. n^{1a} represents an integer of 0 or more.

Examples of the substituent represented by R^{A1a} include the same group as the substituent which may be contained in the carboxylic acid anhydride structure described above, and the same is applied to the preferred range.

Z^{1a} is preferably an alkylene group having 2 to 4 carbon atoms, more preferably an alkylene group having 2 or 3 carbon atoms, and particularly preferably an alkylene group having 2 carbon atoms.

The partial structure represented by Formula P-1 may be condensed or bonded to another ring structure to form a polycyclic structure, but it is preferable that a polycyclic structure is not formed.

Examples of another ring structure referred to herein include the same ring structure as the above-described another ring structure which may be condensed or bonded to the carboxylic acid anhydride structure, and the same is applied to the preferred range.

n^{1a} represents an integer of 0 or more.

In a case where Z^{1a} represents an alkylene group having 2 to 4 carbon atoms, n^{1a} is preferably an integer of 0 to 4, more preferably an integer of 0 to 2, and still more preferably 0.

In a case where n^{1a} represents an integer of 2 or more, a plurality of R^{A1a}'s may be the same or different from each other. Further, the plurality of R^{A1a}'s may be bonded to each other to form a ring but are preferably not bonded to each other to form a ring.

The constitutional unit having a carboxylic acid anhydride structure is preferably a constitutional unit derived from an unsaturated carboxylic acid anhydride, more preferably a constitutional unit derived from an unsaturated cyclic carboxylic acid anhydride, still more preferably a constitutional unit derived from an unsaturated aliphatic cyclic carboxylic acid anhydride, even still more preferably a constitutional unit derived from maleic acid anhydride or itaconic acid anhydride, and particularly preferably a constitutional unit derived from maleic acid anhydride.

Hereinafter, specific examples of the constitutional unit having a carboxylic acid anhydride structure will be mentioned, but the constitutional unit having a carboxylic acid anhydride structure is not limited to these specific examples.

In the following constitutional units, Rx represents a hydrogen atom, a methyl group, a CH₂OH group, or a CF₃ group, and Me represents a methyl group.

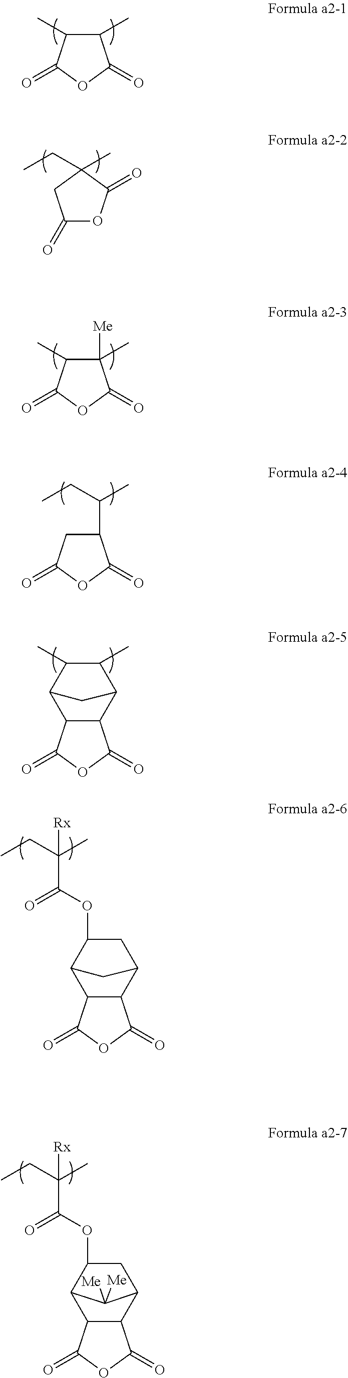

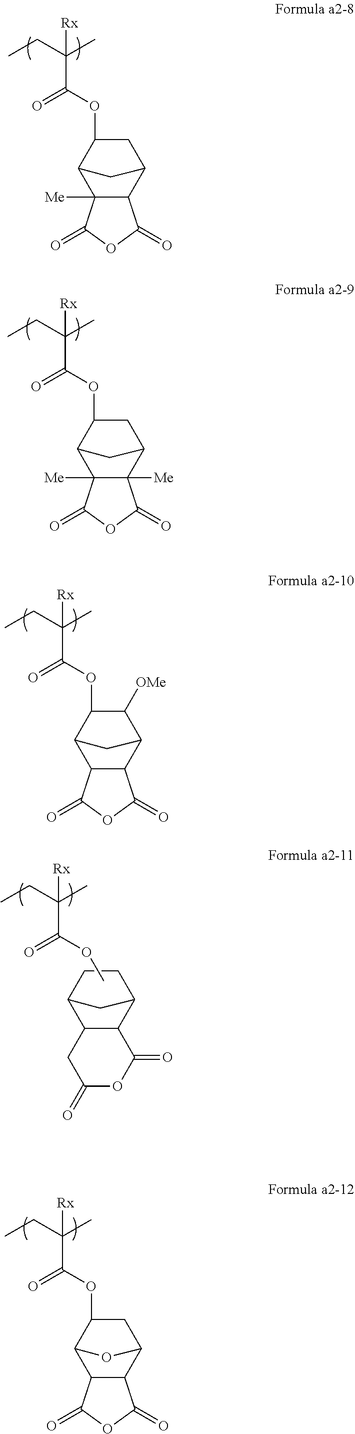

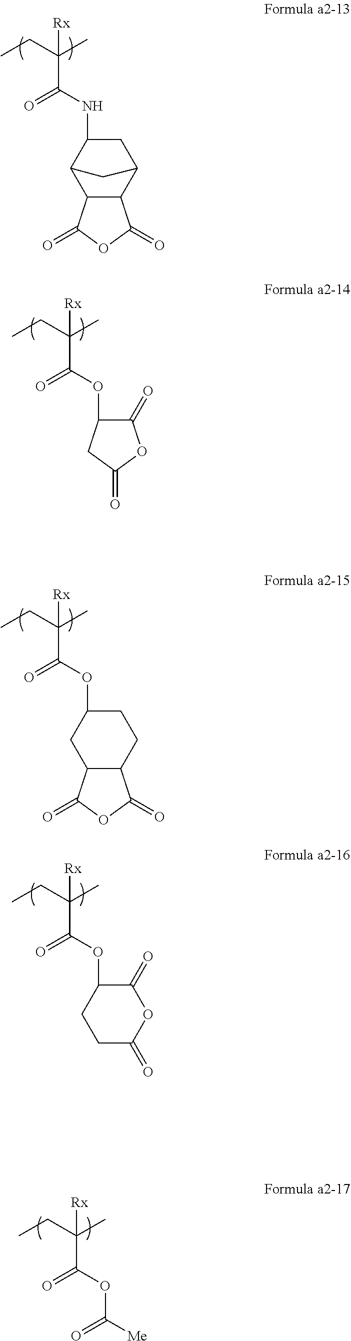

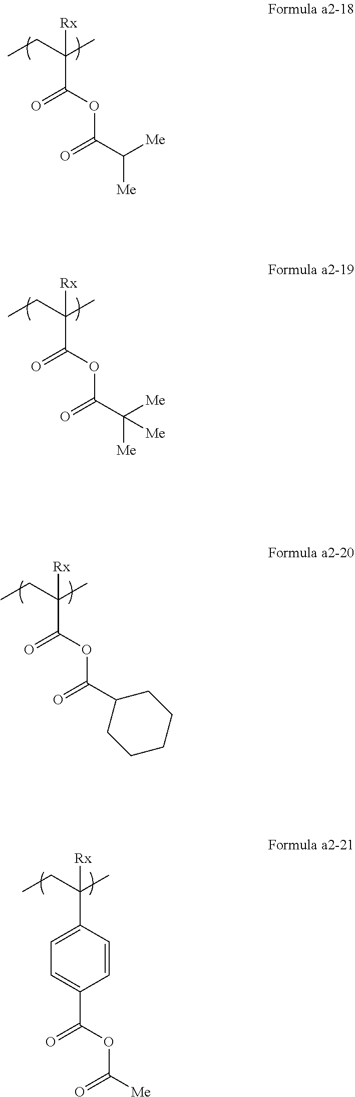

The constitutional unit having a carboxylic acid anhydride structure is preferably at least any one of constitutional units represented by Formulae a2-1 to a2-21 and more preferably any one of the constitutional units represented by Formulae a2-1 to a2-21.

From the viewpoint of developability and moisture permeability of the cured film obtained, the constitutional unit having a carboxylic acid anhydride structure preferably contains at least one of the constitutional unit represented by Formula a2-1 or the constitutional unit represented by Formula a2-2, and more preferably contains the constitutional unit represented by formula a2-1.

The content of the constitutional unit (the total content of the constitutional units in a case of two or more kinds, the same is applied hereinafter) having a carboxylic acid anhydride structure in the specific polymer B is preferably 0% by mole to 60% by mole, more preferably 5% by mole to 40% by mole, and still more preferably 10% by mole to 35% by mole, with respect to the total amount of the specific polymer B.

In the present disclosure, in a case where the content of the “constitutional unit” is specified in terms of the molar ratio, the “constitutional unit” has the same meaning as the “monomer unit”. In addition, in the present disclosure, the “monomer unit” may be modified after polymerization by a polymer reaction or the like. The same is applied to the following.

The specific polymer B preferably contains at least one constitutional unit represented by Formula P-2, whereby the moisture permeability of the obtained cured film becomes lower, and the strength thereof further improves.

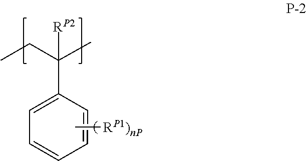

In Formula P-2, R^{P1} represents a hydroxyl group, an alkyl group, an aryl group, an alkoxy group, a carboxy group, or a halogen atom, R^{P2} represents a hydrogen atom, an alkyl group, or an aryl group, and nP represents an integer of 0 to 5. In a case where nP represents an integer of two or more, two or more R^{P1}'s may be the same or different from each other.

R^{P1} is preferably an alkyl group having 1 to 10 carbon atoms, an aryl group having 6 to 12 carbon atoms, an alkoxy group having 1 to 10 carbon atoms, a carboxy group, a F atom, a Cl atom, a Br atom, or an I atom, and more preferably an alkyl group having 1 to 4 carbon atoms, a phenyl group, an alkoxy group having 1 to 4 carbon atoms, a Cl atom, or a Br atom.

R^{P2} is preferably a hydrogen atom, an alkyl group having 1 to 10 carbon atoms, or an aryl group having 6 to 12 carbon atoms, more preferably a hydrogen atom or an alkyl group having 1 to 4 carbon atoms, still more preferably a hydrogen atom, a methyl group, or an ethyl group, and particularly preferably a hydrogen atom.

nP is preferably an integer of 0 to 3, more preferably 0 or 1, and still more preferably 0.

The constitutional unit represented by Formula P-2 is preferably a constitutional unit derived from a styrene compound.

Examples of the styrene compound include styrene, p-methylstyrene, α-methylstyrene, α, p-dimethylstyrene, p-ethylstyrene, p-t-butylstyrene, and 1,1-diphenylethylene, and styrene or α-methylstyrene is preferable, and styrene is particularly preferable.

The styrene compound for forming the constitutional unit represented by Formula P-2 may be only one kind or two or more kinds.

In a case where the specific polymer B contains the constitutional unit represented by Formula P-2, the content of the constitutional unit (the total content of the constitutional units in a case of two or more kinds, the same is applied hereinafter) represented by Formula P-2 in the specific polymer B is preferably 5% by mole to 90% by mole, more preferably 30% by mole to 90% by mole, and still more preferably 40% by mole to 90% by mole, with respect to the total amount of the specific polymer B.

The specific polymer B may contain at least one of other constitutional units other than the constitutional unit having a carboxylic acid anhydride structure and the constitutional unit represented by Formula P-2.

The other constitutional units preferably do not contain an acid group.

The other constitutional units are not particularly limited, and examples thereof include a constitutional unit derived from a monofunctional ethylenic unsaturated compound.

As the monofunctional ethylenic unsaturated compound, a conventionally known compound can be used without particular limitation, and examples thereof include (meth)acrylic acid derivatives such as methyl (meth)acrylate, ethyl (meth)acrylate, n-butyl (meth)acrylate, 2-ethylhexyl (meth)acrylate, Carbitol (meth)acrylate, cyclohexyl (meth)acrylate, benzyl (meth)acrylate, and epoxy (meth)acrylate; N-vinyl compounds such as N-vinylpyrrolidone and N-vinylcaprolactam; and derivatives of allyl compounds such as allyl glycidyl ether.

The content of the other constitutional unit (the total content of the constitutional units in a case of two or more kinds) in the specific polymer B is preferably 10% by mass to 100% by mass and more preferably 50% by mass to 100% by mass, with respect to the total amount of the specific polymer B.

The weight-average molecular weight of the binder polymer is not particularly limited, but it is preferably more than 3,000, more preferably more than 3,000 and 60,000 or less, and still more preferably 5,000 to 50,000.

The binder polymer may be used alone or may contain two or more kinds.

From the viewpoint of the strength of the cured film to be obtained and the handleability of the transfer film, the content of the binder polymer is preferably 10% by mass to 90% by mass, more preferably 20% by mass to 80% by mass, and still more preferably 30% by mass to 70% by mass, with respect to the total solid content of the photosensitive composition.

The mass ratio (MB ratio) of the content of the ethylenic unsaturated compound to the content of the binder polymer in the photosensitive composition is preferably 0.1 or more and more preferably 0.2 or more. In addition, the upper limit of the MB ratio is preferably 0.5 or less and more preferably 0.4 or less.

Surfactant

The photosensitive composition preferably contains a surfactant from the viewpoint of film thickness uniformity.

As the surfactant, any one of an anionic, a cationic, a nonionic (non-ionic), or an amphoteric surfactant can be used, but the preferred surfactant is a nonionic surfactant.

Examples of the nonionic surfactant include polyoxyethylene higher alkyl ethers, polyoxyethylene higher alkyl phenyl ethers, polyoxyethylene glycol higher fatty acid diesters, silicone-based surfactants, and fluorine-based surfactants. In addition, examples of the trade name thereof include each of the series such as KP (manufactured by Shin-Etsu Chemical Co., Ltd.), Polyflow (manufactured by Kyoeisha Chemical Co., Ltd.), F-top (manufactured by JEMCO Inc.), MEGAFACE (manufactured by DIC CORPORATION), Florard (manufactured by Sumitomo 3M Limited), AsahiGuard and Surflon (manufactured by AGC Inc.), PolyFox (manufactured by OMNOVA Solutions Inc.), and SH-8400 (manufactured by DuPont Toray Specialty Materials K.K.).

Further, preferred examples of the surfactant include a copolymer containing a constitutional unit A and a constitutional unit B represented by Formula I-1 and having a polystyrene-equivalent weight-average molecular weight (Mw) of 1,000 or more and 10,000 or less, which is measured by gel permeation chromatography using tetrahydrofuran (THF) as a solvent.

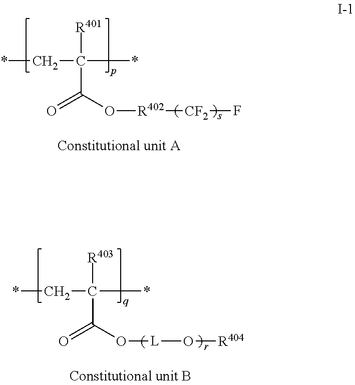

In Formula (I-1), R⁴⁰¹ and R⁴⁰³ each independently represent a hydrogen atom or a methyl group, R⁴⁰² represents a linear alkylene group having 1 or more and 4 or fewer carbon atoms, R⁴⁰⁴ represents a hydrogen atom or an alkyl group having 1 or more and 4 or fewer carbon atoms, L represents an alkylene group having 3 or more and 6 or fewer carbon atoms, p and q each are a mass percentage representing a polymerization ratio, where p represents a numerical value of 10% by mass or more and 80% by mass or less and q represents a numerical value of 20% by mass or more and 90% by mass or less, r represents an integer of 1 or more and 18 or less, s represents an integer of 1 or more and 10 or less, and * represents a bonding position with other structure.

L is preferably a branched alkylene group represented by Formula (I-2). R⁴⁰⁵ in Formula (I-2) represents an alkyl group having 1 or more and 4 or fewer carbon atoms, is preferably an alkyl group having 1 or more and 3 or fewer carbon atoms, and is more preferably an alkyl group having 2 or 3 carbon atoms, in terms of compatibility and wettability to the surface to be coated. The sum (p+q) of p and q is preferably p+q=100, that is, 100% by mass.

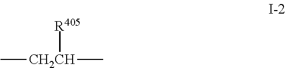

The weight-average molecular weight (Mw) of the copolymer is preferably 1,500 or more and 5,000 or less.

In addition, the surfactants described in paragraph 0017 of JP4502784B and paragraphs 0060 to 0071 of JP2009-237362A can also be used.

The surfactant may be used alone or in a combination of two or more thereof.

The amount of the surfactant to be added is preferably 10% by mass or less, more preferably 0.001% by mass to 10% by mass, and still more preferably 0.01% by mass to 3% by mass, with respect to the total solid content of the photosensitive composition.

<Polymerization Inhibitor>

The photosensitive composition may contain at least one polymerization inhibitor.

As the polymerization inhibitor, for example, the thermal polymerization inhibitor (also referred to as a polymerization inhibitor) described in paragraph 0018 of JP4502784B can be used.

Among them, phenothiazine, phenoxazine, or 4-methoxyphenol can be suitably used.

In a case where the photosensitive composition contains a polymerization inhibitor, the content of the polymerization inhibitor is preferably 0.01% by mass to 3% by mass, more preferably 0.01% by mass to 1% by mass, and still more preferably 0.01% by mass to 0.8% by mass, with respect to the total solid content of the photosensitive composition.

Hydrogen Donating Compound

The photosensitive composition preferably further contains a hydrogen donating compound.

In the present disclosure, the hydrogen donating compound has an action of further improving the sensitivity of the photopolymerization initiator to active rays, suppressing the inhibition of polymerization of a polymerizable compound by oxygen.

Examples of the hydrogen donating compound include amines such as the compounds described in M. R. Sander et al., “Journal of Polymer Society”, Vol. 10, p. 3173 (1972), JP1969-020189B (JP-544-020189B), JP1976-082102A (JP-551-082102A), JP1977-134692A (JP-552-134692A), JP1984-138205A (JP-559-138205A), JP1985-084305A (JP-560-084305A), JP1987-018537A (JP-562-018537A), JP1989-033104A (JP-564-033104A), and Research Disclosure No. 33825. Specific examples thereof include triethanolamine and p-dimethylaminobenzoic acid ethyl ester, p-formyldimethylaniline, and p-methylthiodimethylaniline.

Further, other examples of the hydrogen donating compound include an amino acid compound (for example, N-phenylglycine), an organometallic compound described in JP1973-042965B (JP-548-042965B) (for example, tributyl tin acetate), a hydrogen donor described in JP1980-034414A (JP-555-034414A), and a sulfur compound described in JP-1994-308727A (JP-H6-308727A) (for example, trithiane).

From the viewpoint of improving the curing rate by balancing the polymerization growth rate with the chain transfer, the content of each of these hydrogen donating compounds is preferably in a range of 0.1% by mass or more and 30% by mass or less, more preferably in a range of 1% by mass or more and 25% by mass or less, and still more preferably in a range of 0.5% by mass or more and 20% by mass or less, with respect to the total solid content of the photosensitive composition.

Other Components

The photosensitive composition may contain other components other than the components described above.

Examples of the other components include a heterocyclic compound, a thiol compound, a thermal polymerization inhibitor described in paragraph 0018 of JP4502784B, and another additive described in paragraphs 0058 to 0071 of JP2000-310706A.

Further, as the other components, the photosensitive composition may contain at least one kind of particles (for example, metal oxide particles) for the purpose of adjusting the refractive index and the light transmittance.

The metal of the metal oxide particles includes semimetals such as B, Si, Ge, As, Sb, and Te. From the viewpoint of the transparency of the cured film, the average primary particle diameter of the particles (for example, metal oxide particles) is preferably 1 nm to 200 nm and more preferably 3 nm to 80 nm. The average primary particle diameter is calculated by measuring the particle diameters of 200 particles randomly selected using an electron microscope and arithmetically averaging the measurement results. In a case where the shape of the particle is not spherical, the longest side of the particle is regarded as the particle diameter.

The content of the particles is preferably 0% by mass to 35% by mass, more preferably 0% by mass to 10% by mass, still more preferably 0% by mass to 5% by mass, even still more preferably 0% by mass to 1% by mass, and particularly preferably 0% by mass (that is, the particles are not contained in the photosensitive composition), with respect to the total solid content of the photosensitive composition.

In addition, the photosensitive composition may contain a trace amount of a coloring agent (pigment, dye, or the like) other than the carbon nano-tube as the other components.

Specifically, the content of the coloring agent other than the carbon nano-tube in the photosensitive composition is preferably less than 1% by mass and more preferably less than 0.1% by mass, with respect to the total solid content of the photosensitive composition.

Solvent

The photosensitive composition preferably further contains a solvent from the viewpoint of layer formation by coating.

As the solvent, a commonly used solvent can be used without particular limitation.

The solvent is preferably an organic solvent.

Examples of the organic solvent include methyl ethyl ketone, propylene glycol monomethyl ether, propylene glycol monomethyl ether acetate (also known as 1-methoxy-2-propyl acetate), diethylene glycol ethyl methyl ether, cyclohexanone, methyl isobutyl ketone, butyl acetate, propyl acetate, isobutyl acetate, isopropyl acetate, ethyl lactate, methyl lactate, caprolactam, n-propanol, and 2-propanol. Moreover, the solvent to be used may contain a mixed solvent which is a mixture of these compounds.

The solvent is preferably at least one solvent selected from the group consisting of butyl acetate and propyl acetate.

In a case where a solvent is used, the content of solid content of the photosensitive composition is preferably 5% by mass to 80% by mass, more preferably 5% by mass to 40% by mass, and particularly preferably 5% by mass to 30% by mass, with respect to the total amount of the photosensitive composition.

In a case where a solvent is used, the viscosity (25° C.) of the photosensitive composition is preferably 1 mPa·s to 50 mPa·s, more preferably 2 mPa·s to 40 mPa·s, and particularly preferably 3 mPa·s to 30 mPa·s, from the viewpoint of coatability.

The viscosity is measured by using, for example, VISCOMETER TV-22 (manufactured by TOKI SANGYO CO., LTD.).

In a case where the photosensitive composition contains a solvent, the surface tension (25° C.) of the photosensitive composition is preferably 5 mN/m to 100 mN/m, more preferably 10 mN/m to 80 mN/m, and particularly preferably 15 mN/m to 40 mN/m, from the viewpoint of coatability.

The surface tension is measured by using, for example, Automatic Surface Tensiometer CBVP-Z (manufactured by Kyowa Interface Science Co., Ltd.).

As the solvent, a solvent described in paragraphs 0054 and 0055 of US2005/0282073A can also be used, the contents of which are incorporated in the present specification by reference.

Further, as the solvent, an organic solvent (a high boiling point solvent) having a boiling point of 180° C. to 250° C. can be used, as necessary.

<<Reflectance of Colored Layer>>

From the viewpoint of visibility of the displayed contents on the LED display, in the front member of an LED display, the specular reflectance of the colored layer is preferably 4% or less and the diffuse reflectance of the colored layer is preferably 0.5% or less, the specular reflectance is more preferably 1% or less and the diffuse reflectance is more preferably 0.5% or less, the specular reflectance is still more preferably 0.5% or less and the diffuse reflectance is still more preferably 0.2% or less, and the specular reflectance is particularly preferably 0.1% or less and the diffuse reflectance is particularly preferably 0.1% or less, on the side on which the uneven shape is provided.

In the present disclosure, the specular reflectance is a reflectance measured by a measurement method (Specular Component Include, SCI) in which regular reflection is included, and the diffuse reflectance is a reflectance measured by a measurement method (Specular Component Exclude, SCE) in which regular reflection is excluded.

In the present disclosure, the measurement method for the specular reflectance and the diffuse reflectance of the colored layer on the side on which the uneven shape is provided measures the values of SCI reflectance and SCE reflectance of the colored layer on the surface on the side on which the uneven shape is provided, by using CM-700D manufactured by Konica Minolta, Inc. The measurement is carried out in the range of 360 nm to 740 nm in increments of 10 nm, and as the representative value of the reflectance, the values at 550 nm are adopted as the specular reflectance and the diffuse reflectance described above.

<<Tint of Colored Layer>>

In the front member of an LED display, the tint L value of the colored layer on the side on which the uneven shape is provided is preferably 20 or less, and preferably 10 or less, still more preferably 5 or less, and particularly preferably 2 or less, from the viewpoint of visibility of the displayed contents on the LED display.

In the present disclosure, the measurement method for the tint L value (brightness) of the colored layer on the side on which the uneven shape is provided is performed in the same manner as the measurement method for the specular reflectance and the diffuse reflectance using the CM-700D manufactured by Konica Minolta, Inc., and the tint L value is measured in the range of 360 nm to 740 nm in increments of 10 nm on the surface of the colored layer on the side on which the uneven shape is provided.

<Support>

The front member of an LED display according to the present disclosure has a support.

The support is not particularly limited, and a conventionally known support can be used.

Examples of the support include a resin film, a glass substrate, a ceramic substrate, a metal substrate, a semiconductor substrate, and a substrate having an LED element.

Further, the support may have structures conventionally known in the LED display, such as a wire, an insulating layer, a light transmission suppressing layer, a light non-transmission layer, and a protective layer, as necessary.

In addition, the thickness of the support is not particularly limited and can be appropriately set as desired.

Among them, the support is preferably a support that can be peeled off from the colored layer, that is, a temporary support.

The temporary support is preferably a film and more preferably a resin film.

As the temporary support, a film that is flexible and is not significantly deformed, shrunk, or elongated under pressurization, or under pressurization and heating can be used.

Examples of such a film include a polyethylene terephthalate film, a cellulose triacetate film, a polystyrene film, a polyimide film, and a polycarbonate film.

Among them, a biaxially stretched polyethylene terephthalate film is particularly preferable.

Further, it is preferable that the film used as the temporary support has no deformation such as wrinkles, and no scratch.

The thickness of the temporary support is not particularly limited, but it is preferably 5 μm to 200 μm and particularly preferably 10 μm to 150 μm, from the viewpoint of easy handleability and versatility.

<Other Layers and Structures>

the front member of an LED display according to the present disclosure may have layers and structures (other layers and structures) other than the support and the colored layer.

Examples of the other layers and structures include conventionally known layers and structures for the LED display and the transfer material.

Further, a protective layer for protecting the uneven shape may be provided on the colored layer.

The material of the protective layer is not particularly limited, and examples thereof include a conventionally known resin and a conventionally known cured resin.

Further, in a case where the support is a temporary support, an adhesive layer may be provided between the support and the colored layer.

As the material of the adhesive layer, a known adhesive and a gluing agent can be used.

(Method for Manufacturing Front Member of LED Display)

A method for manufacturing a front member of an LED display according to the present disclosure is not particularly limited, but it preferably includes a step of forming a photosensitive layer on a support using a photosensitive composition containing at least one compound selected from the group consisting of a binder polymer and an ethylenic unsaturated compound, and a carbon nano-tube, a step of forming an uneven shape on the surface of the photosensitive layer opposite to the side on which the support is provided, and a step of patterning the photosensitive layer.

<Step of Forming Photosensitive Layer>

The method for manufacturing a front member of an LED display according to the present disclosure preferably includes a step (also referred to as a “photosensitive layer forming step”) of forming a photosensitive layer on a support using a photosensitive composition containing at least one compound selected from the group consisting of a binder polymer and an ethylenic unsaturated compound, and a carbon nano-tube.

The method for forming a photosensitive layer is not particularly limited, but it is preferably a method in which the photosensitive composition described above is applied onto a support and dried to form the photosensitive layer.

In addition, it is preferable to produce a carbon nano-tube dispersion product described above and prepare photosensitive composition using the carbon nano-tube dispersion product described above.

The method for applying and the method for drying the photosensitive composition is not particularly limited, and known methods can be used.

The binder polymer in the method for manufacturing the front member of an LED display according to the present disclosure has the same meaning as the binder polymer described above in the front member of an LED display according to the present disclosure, and the same is applied to the preferred aspect.

The ethylenic unsaturated compound in the method for manufacturing the front member of an LED display according to the present disclosure has the same meaning as the ethylenic unsaturated compound described above in the front member of an LED display according to the present disclosure, and the same is applied to the preferred aspect.

The preferred average thickness of the photosensitive layer in the method for manufacturing the front member of an LED display according to the present disclosure has the same meaning as the preferred average thickness of the colored layer described above in the front member of an LED display according to the present disclosure.

<Step of Forming Uneven Shape>

The method for manufacturing a front member of an LED display according to the present disclosure preferably includes a step (also referred to as an “uneven shape forming step”) of forming an uneven shape on the surface of the photosensitive layer opposite to a side on which the support is provided.

The method for forming an uneven shape is not particularly limited; however, preferred examples thereof include a method in which a stamper having an uneven shape is pressed on the surface of the photosensitive layer opposite to a side on which the support is provided, thereby forming an uneven shape, or a method in which the surface of the photosensitive layer opposite to a side on which the support is provided is irradiated with ion beams, thereby forming an uneven shape.

The preferred aspect of the uneven shape in the method for manufacturing the front member of an LED display according to the present disclosure is the same as the preferred aspect of the uneven shape described above in the front member of an LED display according to the present disclosure.

In a case where a stamper having an uneven shape is used, the photosensitive layer is preferably a layer containing an ethylenic unsaturated compound.

The stamper having an uneven shape is preferably a stamper having a moth-eye structure.

The moth-eye structure is an uneven shape having a period (pitch) of less than 780 nm, which is the wavelength of visible light and with which the uneven shape can be suitably formed.

The stamper having an uneven shape may be a resin film having an uneven shape or a metal member (for example, a plate-shaped or cylindrical metal member) having an uneven shape.

The stamper having an uneven shape is preferably a resin film stamper obtained by stamping a mold on an object to be molded such as a resin film and transferring a fine molding pattern in a micrometer scale or a nanometer scale. The mold for transferring the mold pattern is preferably a mold formed of silicon or metal. In the mold formed of silicon, a pattern is formed on a silicon substrate or the like by a semiconductor fine processing technique such as photolithography or etching. In addition, the mold formed of metal is formed by subjecting a surface of a mold formed of silicon to metal plating by an electroforming method (for example, a nickel plating method) and peeling off the metal plating layer.

Examples of the resin film include a polyethylene terephthalate film, a cellulose triacetate film, a polystyrene film, a polyimide film, and a polycarbonate film.

In a case where a stamper having an uneven shape is used, the conditions for the above pressing are not particularly limited and may be appropriately selected depending on the physical properties of the photosensitive layer, the material of the stamper, and the like; however, the linear pressure at the time of pressing is preferably 5 N/cm to 1,000 N/cm, more preferably 10 N/cm to 500 N/cm, and particularly preferably 20 N/cm to 200 N/cm. The temperature at the time of pressing is preferably 0° C. to 200° C., more preferably 25° C. to 150° C., and particularly preferably 50° C. to 120° C.

From the viewpoint of the easiness of forming the uneven shape, the step of forming the uneven shape is preferably a step of pressing a stamper having a moth-eye structure against the surface of the photosensitive layer opposite to the side on which the support is provided, thereby forming an uneven shape.

In a case where an ion beam is used to form the uneven shape, the irradiation with the ion beam may be performed before the curing of the photosensitive layer, after the curing of the photosensitive layer, or after the pattern formation but is preferably performed after the curing or the pattern formation.

The irradiation conditions of the ion beam are not particularly limited, and conventionally known conditions can be appropriately combined. With respect to the ion beam, it is possible to appropriately set, for example, the irradiation position, the irradiation intensity, the level of the irradiation intensity depending on the irradiation position, the intensity and the irradiation time, the type of ions to be generated, the flow rate, voltage, and degree of vacuum of the gas for forming ions, depending on the composition of the photosensitive layer and the uneven shape to be formed.

In addition, examples of the formation of the uneven shape by the ion beam include sputtering of the surface of the photosensitive layer by a focused ion beam using gallium ions.

<Step of Patterning>

The method for manufacturing a front member of an LED display according to the present disclosure preferably includes a step (also referred to as a “patterning step”) of patterning the photosensitive layer.

The patterning step is not particularly limited, and a conventionally known patterning method can be used; however, the patterning step preferably includes a step (also referred to as a “pattern exposure step”) of pattern-exposing the photosensitive layer and a step (also referred to as a “development step”) of developing the pattern-exposed photosensitive layer.

<<Pattern Exposure Step>>

The pattern exposure step is a step of pattern-exposing the photosensitive layer. Here, the pattern exposure refers to an aspect of exposing patternwise, that is, an aspect in which an exposed portion and a non-exposed portion are present.

For example, in a case where the photosensitive layer is a negative type photosensitive layer, for example, in a case where the photosensitive layer is a layer containing an ethylenic unsaturated compound and a photopolymerization initiator, the exposed portion of the photosensitive layer in the pattern exposure is cured and finally becomes a cured film. The non-exposed portion of the photosensitive layer in the pattern exposure is not cured and is removed (dissolved) by the developer in the next development step. In the non-exposed portion, an opening of the cured film may be formed after the development step.

The pattern exposure may be the exposure through a mask or a digital exposure using a laser or the like.

As the light source for pattern exposure, any light source capable of emitting light in a wavelength range (for example, 365 nm or 405 nm) in which the photosensitive layer is capable of being cured can be appropriately selected and used. Examples of the light source include a variety of lasers, a light emitting diode (LED), an ultra-high pressure mercury lamp, a high pressure mercury lamp, and a metal halide lamp. Exposure amount is preferably 5 mJ/cm² to 2,000 mJ/cm² and more preferably 10 mJ/cm² to 1,000 mJ/cm².

In a case where the photosensitive layer is formed on the support using a transfer film, the pattern exposure may be performed after the temporary support is peeled off, or the exposure may be performed before the temporary support is peeled off and then the temporary support may be peeled off.

<<Development Step>>

The development step is a step of developing (that is, dissolving the non-exposed portion in the pattern exposure in a developer) the pattern-exposed photosensitive layer.

The developer used for development is not particularly limited, and a known developer such as the developer described in JP1993-072724A (JP-H5-072724A) can be used.

As the developer, an alkaline aqueous solution can be preferably used.

Examples of the alkaline compound that can be contained in the alkaline aqueous solution include sodium hydroxide, potassium hydroxide, sodium carbonate, potassium carbonate, sodium hydrogencarbonate, potassium hydrogencarbonate, tetramethylammonium hydroxide, tetraethyl ammonium hydroxide, tetrapropyl ammonium hydroxide, tetrabutylammonium hydroxide, and choline (2-hydroxyethyltrimethylammonium hydroxide).

The pH of the alkaline aqueous solution at 25° C. is preferably 8 to 13, more preferably 9 to 12, and particularly preferably 10 to 12.

The content of the alkaline compound in the alkaline aqueous solution is preferably 0.1% by mass to 5% by mass and more preferably 0.1% by mass to 3% by mass, with respect to the total amount of the alkaline aqueous solution.

The developer may contain an organic solvent that is miscible with water.

Examples of the organic solvent include methanol, ethanol, 2-propanol, 1-propanol, butanol, diacetone alcohol, ethylene glycol monomethyl ether, ethylene glycol monoethyl ether, ethylene glycol mono-n-butyl ether, benzyl alcohol, acetone, methyl ethyl ketone, cyclohexanone, ε-caprolactone, γ-butyrolactone, dimethylformamide, dimethylacetamide, hexamethylphosphoramide, ethyl lactate, methyl lactate, ε-caprolactam, and N-methylpyrrolidone.

The concentration of the organic solvent is preferably 0.1% by mass to 30% by mass.

The developer may contain a conventionally known surfactant. The concentration of the surfactant is preferably 0.01% by mass to 10% by mass.

Examples of the development type include a puddle development, a shower development, a shower and spin development, and a dip development.

In a case where a shower development is performed, the non-exposed portion of the photosensitive layer may be removed by spraying the developer on the pattern-exposed photosensitive layer in a showered shape.

Further, after the development, it is preferable to remove the development residue by rubbing with a brush or the like while spraying a cleaning agent or the like with a shower.

The liquid temperature of the developer is preferably 20° C. to 40° C.

The development step may include a step of performing the above-described development and a step of heat-treating the cured film obtained by the above-described development (hereinafter, also referred to as “post-baking”).

In a case where the substrate is a resin substrate, the post-baking temperature is preferably 100° C. to 160° C. and more preferably 130° C. to 160° C.

The resistance value of the transparent electrode pattern can also be adjusted by this post-baking.

In addition, the development step may include a step of performing the above-described development and a step of exposing the cured film obtained by the above-described development (hereinafter, also referred to as “post-exposure”).

In a case where the development step includes the post-exposure step and the post-baking step, it is preferable to perform post-exposure and then post-baking.

For pattern exposure, development, and the like, for example, the description in paragraphs 0035 to 0051 of JP2006-023696A can be referred to.

The method for manufacturing the front member of an LED display according to the present disclosure may include other steps other than the steps described above. As the other steps, a step (for example, a cleaning step) that may be provided in a typical photolithography step can be applied without particular limitation.

### EXAMPLES

Hereinafter, the present disclosure will be described in more detail with reference to Examples. The materials, amounts used, ratios, treatment contents, treatment procedures, and the like described in Examples below can be appropriately changed without departing from the spirit of the present disclosure. Accordingly, the scope of the present disclosure is not limited to the specific examples described below. Unless otherwise specified, “parts” and “%” are based on mass.

<Production of Black Dispersion Product K1>

A glass bottle was charged with 2.0 parts by mass of a carbon nano-tube (CNT, single wall layer, average fiber diameter: 20 nm), 6.0 parts by mass of a styrene-based/acrylic polymer (Joncryl 683, manufactured by Johnson Polymer LLC), 92.0 parts by mass of butyl acetate, and dispersion was performed for 1 hour using a paint conditioner using zirconia beads of 0.5 mmφ as a media, thereby obtaining a black dispersion product K1.

The following coating liquid was prepared as a coating liquid for forming a black layer using the black dispersion product K1.

<Preparation of Black Layer Coating Liquid 1>

Black dispersion product K1: 20 parts by mass

Propyl acetate: 7.37 parts by mass

Dipentaerythritol hexaacrylate (manufactured by Nippon Kayaku Co., Ltd.): 5.63 parts by mass

45% by mass propylene glycol monomethyl ether acetate solution of benzyl methacrylate/methacrylic acid random copolymer (molar ratio: 70/30, weight-average molecular weight: 5,000): 18.19 parts by mass

IRGACURE OXE-02 (manufactured by BASF SE): 0.55 parts by mass

MEGAFACE F551 (manufactured by DIC Corporation): 0.09 parts by mass

<Production of Black Film>

A coating liquid for a black layer consisting of a black layer coating liquid 1 was applied onto a 75 μm-thick polyethylene terephthalate film temporary support (protective film 1) using a slit-shaped nozzle and then dried. In this manner, a black resin layer having a dry film thickness of 8.0 μm was provided on the temporary support, and finally, a protective film 2 (a 12 μm-thick polypropylene film) was pressure-bonded as a protective peeling-off layer. In this manner, a transfer material in which the temporary support, the black layer, and the protective peeling-off layer were integrated was produced, and the sample name thereof was designated as transfer material black 1.

### Example 1

### Manufacturing Example of Non-Reflective Black Material (Manufacturing Example B)

Using the transfer material black 1, a substrate having a black pattern was produced according to the following steps.

The surface of the black layer naked by peeling off the protective film 2 from the transfer material black 1 which had been cut into a shape of 10 cm×10 cm was superposed on a stamper FMES250/300 (manufactured by SCIVAX Corporation), and stuck by using a laminator Lamic II type (manufactured by Hitachi, Ltd.) at a transport speed of 4 m/min under the conditions of pressurization and heating of a linear pressure of 100 N/cm, an upper roll temperature of 100° C., and a lower roll temperature of 100° C. Thereafter, using a proximity type exposure machine (manufactured by Hitachi High-Tech Corporation) having an ultra-high pressure mercury lamp, proximity exposure was performed from the stamper side at an i line exposure amount of 500 mJ/cm² and with a mask gap of 100 μm through an exposure mask having a hole-shaped light-shielding pattern (diameter: 3 mm), and then the stamper was peeled off.

Next, the black layer of the laminate from which the stamper had been peeled off was developed for 40 seconds using a 1% by mass aqueous solution of sodium carbonate (liquid temperature: 32° C.) as a developer. After the development, pure water was sprayed with a shower for 120 seconds to perform shower washing with pure water, and air was blown to obtain a black pattern image (a front member of an LED display).

### Example 2

### Manufacturing Example of Non-Reflective Black Material (Manufacturing Example A)

Using the transfer material black 1, a substrate having a black pattern was produced according to the following steps.

The surface of the black layer naked by peeling off the protective film 2 from the transfer material black 1 which had been cut into a shape of 10 cm×10 cm was superposed on a stamper (in which the uneven shape had an average height of protrusions of 200 nm and an average pitch of protrusions of 250 nm) produced according to the method disclosed in JP2017-161590A, and unevenness was produced on the surface of the black layer using a laminator Lamic II type (manufactured by Hitachi, Ltd.) at a transport speed of 4 m/min under the conditions of pressurization and heating of a linear pressure of 100 N/cm, an upper roll temperature of 100° C., and a lower roll temperature of 100° C. Thereafter, using a proximity type exposure machine (manufactured by Hitachi High-Tech Corporation) having an ultra-high pressure mercury lamp, proximity exposure was performed from the black layer side at an i line exposure amount of 500 mJ/cm² and with a mask gap of 100 μm through an exposure mask having a hole-shaped light-shielding pattern (diameter: 3 mm).

Next, the black layer was developed for 40 seconds using a 1% by mass aqueous solution of sodium carbonate (liquid temperature: 32° C.) as a developer. After the development, pure water was sprayed with a shower for 120 seconds to perform shower washing with pure water, and air was blown to obtain a black pattern image (a front member of an LED display).

### Example 3 to Example 13

Black pattern images were obtained in the same manner as in Example 1 except that the height of the protrusions to be formed, the average pitch of the protrusions to be formed, the content of the carbon nano-tube, the average fiber diameter of the carbon nano-tube, and the average thickness of the colored layer were changed as shown in Table 1.

### Example 14

A black pattern image was obtained in the same manner as in Example 1 except that the carbon nano-tube (single wall, average fiber diameter: 20 nm) was changed to a carbon nano-tube (multi wall, average fiber diameter: 10 nm). The multi wall carbon nano-tube was produced with reference to the method described in paragraphs 0076 to 0078 of WO16/084697A

### Example 15

A black pattern image was obtained in the same manner as in Example 1 except that dipentaerythritol hexaacrylate in the black layer coating liquid was changed to pentaerythritol tetraacrylate (A-TMMT manufactured by SHIN-NAKAMURA CHEMICAL CO., LTD.).

### Example 16

A black pattern image was obtained in the same manner as in Example 1 except that dipentaerythritol hexaacrylate in the black layer coating liquid was changed to trimethylolpropane triaciylate (A-TMPT manufactured by SHIN-NAKAMURA CHEMICAL CO., LTD.).

### Example 17

A black pattern image was obtained in the same manner as in Example 1 except that dipentaerythritol hexaacrylate in the black layer coating liquid was changed to Viscoat #802 (a mixture of tripentaerythritol acrylate, mono and dipentaerythritol acrylate, and polypentaerythritol acrylate, manufactured by Osaka Organic Chemical Industry Ltd.).

### Example 18

A black pattern image was obtained in the same manner as in Example 1 except that the benzyl methacrylate/methacrylic acid random copolymer in the black layer coating liquid was changed to a polymer D described later, as the solid content.

<Preparation of 36.3% by Mass Solution of Solid Content of Polymer D>

As the binder polymer, a 36.3% by mass solution (solvent: propylene glycol monomethyl ether acetate) of solid content of polymer D having the following structure was used. In the polymer D, the numerical value at the lower right of each constitutional unit indicates the content rate (% by mole) of each constitutional unit.

The 36.3% by mass solution of solid content of polymer D was prepared by the polymerization step and the addition step described below.

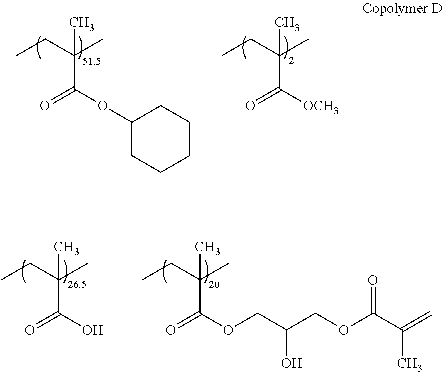

Polymerization Step

60 g of propylene glycol monomethyl ether acetate (manufactured by Sanwa Kagaku Sangyo Co., Ltd., trade name: PGM-Ac) and 240 g of propylene glycol monomethyl ether (manufactured by Sanwa Kagaku Sangyo Co., Ltd., trade name: PGM) were introduced into a 2,000 mL flask. The introduced liquid was heated to 90° C. while stirring at a stirring speed of 250 revolutions per minute (rpm; the same is applied hereinafter).

As the preparation of a dropping liquid (1), 107.1 g of methacrylic acid (manufactured by Mitsubishi Chemical Corporation, trade name: Acryester M), 5.46 g of methyl methacrylate (manufactured by Mitsubishi Gas Chemical Company, Inc., trade name: MMA), and 231.42 g of cyclohexyl methacrylate (manufactured by Mitsubishi Gas Chemical Company, Inc., trade name: CHMA) were mixed and diluted with 60 g of PGM-Ac to obtain the dropping liquid (1).

As the preparation of a dropping liquid (2), 9.637 g of dimethyl 2,2′-azobis(2-methylpropionate) (a polymerization initiator, manufactured by FUJIFILM Wako Pure Chemical Corporation, trade name: V-601) was dissolved in 136.56 g of PGM-Ac to obtain the dropping liquid (2).

The dropping liquid (1) and the dropping liquid (2) were simultaneously added dropwise over 3 hours to the above-described 2,000 mL flask (specifically, a 2,000 mL flask containing a liquid heated to 90° C.). Next, the container of the dropping liquid (1) was washed with 12 g of PGM-Ac, and the washing liquid was dropwise added to the 2,000 mL flask. Next, the container of the dropping liquid (2) was washed with 6 g of PGM-Ac, and the washing liquid was dropwise added to the 2,000 mL flask. During these dropwise additions, the reaction liquid in the 2,000 mL flask was kept at 90° C. and stirred at a stirring speed of 250 rpm. Further, as the post-reaction, stirring was performed at 90° C. for 1 hour.

2.401 g of V-601 was added to the reaction liquid after the post-reaction as the first additional addition of the initiator. Further, the container of V-601 was washed with 6 g of PGM-Ac, and the washing liquid was introduced into the reaction liquid. Thereafter, stirring was performed at 90° C. for 1 hour.

Next, 2.401 g of V-601 was added to the reaction liquid as the second additional addition of the initiator. Further, the container of V-601 was washed with 6 g of PGM-Ac, and the washing liquid was introduced into the reaction liquid. Thereafter, stirring was performed at 90° C. for 1 hour.

Next, 2.401 g of V-601 was added to the reaction liquid as the third additional addition of the initiator. Further, the container of V-601 was washed with 6 g of PGM-Ac, and the washing liquid was introduced into the reaction liquid. Thereafter, stirring was performed at 90° C. for 3 hours.

Addition Step

After stirring at 90° C. for 3 hours, 178.66 g of PGM-Ac was introduced into the reaction liquid. Next, 1.8 g of tetraethylammonium bromide (manufactured by FUJIFILM Wako Pure Chemical Corporation) and 0.8 g of hydroquinone monomethyl ether (manufactured by FUJIFILM Wako Pure Chemical Corporation) were added to the reaction liquid. Further, each of the containers was washed with 6 g of PGM-Ac, and the washing liquid was introduced into the reaction liquid. Thereafter, the temperature of the reaction liquid was raised to 100° C.

Next, 76.03 g of glycidyl methacrylate (manufactured by NOF Corporation, trade name: Blemmer G) was dropwise added to the reaction liquid over 1 hour. Further, the container of Blemmer G was washed with 6 g of PGM-Ac, and the washing liquid was introduced into the reaction liquid. Thereafter, as the addition reaction, stirring was performed at 100° C. for 6 hours.

Next, the reaction liquid was cooled and filtered through a mesh filter (100 meshes) for removing dust to obtain 1,158 g of a solution of the polymer D (solid content concentration: 36.3% by mass). The obtained polymer D had a weight-average molecular weight of 27,000, a number-average molecular weight of 15,000, and an acid value of 95 mgKOH/g.

### Example 19

In Example 1, after the stamper was attached, the temporary support (protective film 1) was peeled off, the following optical clear adhesive (OCA) sheet was attached, and then exposure, peeling-off, development were performed in the same manner as in Example 1 to obtain a black pattern image.

Optical clear adhesive sheet: CLEARFIT JHA200 manufactured by Mitsubishi Chemical Corporation, film thickness: 200 μm, UV curable type

### Comparative Example 1

A black pattern image was obtained in the same manner as in Example 1 except that the carbon nano-tube was changed to carbon black (CB, average particle diameter: 20 nm, MA600 manufactured by Mitsubishi Chemical Corporation).

### Comparative Example 2

A black pattern image was obtained in the same manner as in Comparative Example 1 except that exposure was performed as it was without using the stamper FMES250/300 and without peeling off the protective film and development was performed after the protective film was peeled off.

### Comparative Example 3

A black pattern image was obtained in the same manner as in Example 1 except that exposure was performed as it was without using the stamper FMES250/300 and without peeling off the protective film and development was performed after the protective film was peeled off.

### Comparative Example 4

A black pattern image was obtained in the same manner as in Example 2 except that the carbon nano-tube was changed to carbon black (CB, average particle diameter: 20 nm, MA600 manufactured by Mitsubishi Chemical Corporation).

<Evaluation>

Evaluation of Specular Reflectance (SCI Reflectance) and Diffuse Reflectance (SCE Reflectance)

In the obtained black pattern image, the surface reflectance from the side on which the black pattern was provided was measured to obtain values of specular reflectance and diffuse reflectance by using CM-700D manufactured by Konica Minolta, Inc. The measurement was carried out in the range of 360 nm to 740 nm in increments of 10 nm, the determination was performed based on the values at 550 nm as the representative value of the reflectance, and the evaluation was performed based on the following criteria.

A: Both reflectances of the specular reflectance and the diffuse reflectance are 0.1% or less.

B: The specular reflectance is more than 0.1% and 2.0% or less, the diffuse reflectance is 0.2% or less, or both thereof.

C: The specular reflectance is more than 2.0% and less than 4.0%, the diffuse reflectance is 0.2% or less, or both thereof.

D: The specular reflectance is 4.0% or more, the diffuse reflectance is more than 0.2%, or both thereof.

Visual Evaluation of Reflected Glare

A substrate, on which the black pattern image obtained in each Example and Comparative Example was formed, was placed under a fluorescent lamp (ceiling lighting (fluorescent lamp: 2,500 cd/m²)), and visual evaluation was performed at two angles of 5 degrees and 45 degrees with respect to the bottom surface of the substrate from the left, right, top, and bottom directions to organoleptically evaluate the intensity of the fluorescent lamp reflected in the black pattern image.

A: Scarcely reflected

B: Slightly reflected when looked carefully

C: Slightly reflected

D: Distinctly confirmed from any angle

Measurement of Brightness L Value

Using CM-700D manufactured by Konica Minolta, Inc., the L* value (D65) was calculated simultaneously together with the reflectance measurement.

TABLE 1

| | Colored layer | | | | | | | | | | | | |
|---|---|---|---|---|---|---|---|---|---|---|---|---|---|
| | | Height | Average | | Content of | Average | | | | | | Evaluation | Visual |
| | | of | pitch of | | black | fiber | | | | Brightness | | of SCI | evaluation |
| | | protru- | protru- | Kind of | material | diameter | Average | Reflectance | | L | L | reflectance | of |
| | Manufacturing | sion | sion | black | (% by | of carbon | thickness | (%) | | value | value | and SCE | reflected |
| | method | (nm) | (nm) | material | mass) | nano-tube | (μm) | SCI | SCE | SCI | SCE | reflectance | glare |
| Example 1 | Manufacturing | 200 | 250 | Single | 2.5 | 20 nm | 10 | 0.09 | 0.04 | 1.1 | 0.40 | A | A |
| | example B | | | wall CNT | | | | | | | | | |
| Example 2 | Manufacturing | 200 | 250 | Single | 2.5 | 20 nm | 10 | 0.09 | 0.04 | 1.1 | 0.40 | A | A |
| | example A | | | wall CNT | | | | | | | | | |
| Example 3 | Manufacturing | 200 | 250 | Single | 1.0 | 20 nm | 10 | 0.20 | 0.10 | 1.4 | 1.0 | B | B |
| | example B | | | wall CNT | | | | | | | | | |
| Example 4 | Manufacturing | 200 | 250 | Single | 5.0 | 20 nm | 10 | 0.50 | 0.10 | 2.5 | 1.0 | B | B |
| | example B | | | wall CNT | | | | | | | | | |
| Example 5 | Manufacturing | 200 | 250 | Single | 10.0 | 20 nm | 10 | 2.0 | 0.20 | 1.4 | 2.0 | B | B |
| | example B | | | wall CNT | | | | | | | | | |
| Example 6 | Manufacturing | 200 | 250 | Single | 2.5 | 20 nm | 5 | 0.70 | 0.08 | 3.5 | 0.8 | B | B |
| | example B | | | wall CNT | | | | | | | | | |
| Example 7 | Manufacturing | 200 | 250 | Single | 2.5 | 20 nm | 20 | 0.08 | 0.04 | 1.0 | 0.4 | A | A |
| | example B | | | wall CNT | | | | | | | | | |
| Example 8 | Manufacturing | 200 | 250 | Single | 2.5 | 10 nm | 10 | 0.12 | 0.10 | 1.1 | 1.0 | B | B |
| | example B | | | wall CNT | | | | | | | | | |
| Example 9 | Manufacturing | 200 | 150 | Single | 2.5 | 20 nm | 10 | 0.09 | 0.03 | 1.1 | 0.4 | A | A |
| | example B | | | wall CNT | | | | | | | | | |
| Example 10 | Manufacturing | 250 | 250 | Single | 2.5 | 20 nm | 10 | 0.08 | 0.04 | 1.1 | 0.4 | A | A |
| | example B | | | wall CNT | | | | | | | | | |
| Example 11 | Manufacturing | 250 | 150 | Single | 2.5 | 20 nm | 10 | 0.08 | 0.03 | 1.1 | 0.4 | A | A |
| | example B | | | wall CNT | | | | | | | | | |
| Example 12 | Manufacturing | 200 | 1000 | Single | 2.5 | 20 nm | 10 | 1.50 | 0.20 | 7.5 | 2.0 | B | B |
| | example B | | | wall CNT | | | | | | | | | |
| Example 13 | Manufacturing | 50 | 250 | Single | 2.5 | 20 nm | 10 | 3.50 | 0.10 | 18.0 | 1.0 | C | C |
| | example B | | | wall CNT | | | | | | | | | |
| Example 14 | Manufacturing | 200 | 250 | Multi | 2.5 | 20 nm | 10 | 0.10 | 0.04 | 1.25 | 0.40 | A | A |
| | example B | | | wall CNT | | | | | | | | | |
| Example 15 | Manufacturing | 200 | 250 | Single | 2.5 | 20 nm | 10 | 0.18 | 0.10 | 1.4 | 1.0 | B | B |
| | example B | | | wall CNT | | | | | | | | | |
| Example 16 | Manufacturing | 200 | 250 | Single | 2.5 | 20 nm | 10 | 0.40 | 0.10 | 2.0 | 1.0 | B | B |
| | example B | | | wall CNT | | | | | | | | | |
| Example 17 | Manufacturing | 200 | 250 | Single | 2.5 | 20 nm | 10 | 0.12 | 0.10 | 1.1 | 1.0 | B | B |
| | example B | | | wall CNT | | | | | | | | | |
| Example 18 | Manufacturing | 200 | 250 | Single | 2.5 | 20 nm | 10 | 0.08 | 0.04 | 1.1 | 0.4 | A | A |
| | example B | | | wall CNT | | | | | | | | | |
| Example 19 | Manufacturing | 200 | 250 | Single | 2.5 | 20 nm | 10 | 0.09 | 0.04 | 1.13 | 0.40 | A | A |
| | example B | | | wall CNT | | | | | | | | | |
| Comparative | Manufacturing | 200 | 250 | CB | 2.5 | (20 nm) | 10 | 4.1 | 0.20 | 21.0 | 1.20 | D | D |
| Example 1 | example B | | | | | | | | | | | | |
| Comparative | Manufacturing | — | — | CB | 2.5 | (20 nm) | 10 | 7.0 | 0.25 | 31.9 | 2.24 | D | D |
| Example 2 | example B | | | | | | | | | | | | |
| Comparative | Manufacturing | — | — | Single | 2.5 | 20 nm | 10 | 4.6 | 0.06 | 25.7 | 0.23 | D | D |
| Example 3 | example B | | | wall CNT | | | | | | | | | |
| Comparative | Manufacturing | 200 | 250 | CB | 2.5 | (20 nm) | 10 | 4.5 | 0.20 | 22.0 | 1.2 | D | D |
| Example 4 | example A | | | | | | | | | | | | |

The values in the column of “Average fiber diameter of carbon nano-tube” of Comparative Example 1, Comparative Example 2, and Comparative Example 4 in Table 1 are the values of the average particle diameter of carbon black.

From the results shown in Table 1, it can be seen that in the front members of an LED display of Example 1 to Example 19, both diffuse reflection (SCE) and specular reflection (SCI) have low values as compared with the front members of an LED display of Comparative Examples.

The disclosure of JP2018-183512 filed on Sep. 28, 2018, is incorporated in the present specification by reference in its entirety.

All documents, patent applications, and technical standards described in the present specification are incorporated in the present specification by reference, to the same extent as in the case where each of the documents, patent applications, and technical standards is specifically and individually described.

What is claimed is:

1. A front member of an LED display, comprising:
a support; and
a colored layer containing an organic resin and a carbon nano-tube,
wherein an uneven shape is provided on a surface of the colored layer opposite to a side on which the support is provided.

2. The front member of an LED display according to claim 1, wherein an average height of protrusions in the uneven shape is 150 nm to 1,000 nm.

3. The front member of an LED display according to claim 1, wherein an average pitch of protrusions in the uneven shape is 50 nm to 500 nm.

4. The front member of an LED display according to claim 1, wherein an average thickness of the colored layer is 5 μm or more.

5. The front member of an LED display according to claim 1, wherein a content of the carbon nano-tube in the colored layer is 0.5% by mass to 10% by mass with respect to a total mass of the colored layer.

6. The front member of an LED display according to claim 1, wherein an average fiber diameter of the carbon nano-tube is 8 nm to 25 nm.

7. The front member of an LED display according to claim 1, wherein in the front member of an LED display, a specular reflectance of the colored layer is 1% or less and a diffuse reflectance of the colored layer is 0.5% or less on a side on which the uneven shape is provided.

8. The front member of an LED display according to claim 1, wherein in the front member of an LED display, a tint L value of the colored layer on a side on which the uneven shape is provided is 2 or less.

9. The front member of an LED display according to claim 1, wherein the colored layer contains a resin obtained by polymerizing an ethylenic unsaturated compound.

10. The front member of an LED display according to claim 1, wherein the front member of an LED display is used for removing stray light.

11. An LED display, comprising the front member of an LED display according to claim 1.

12. A method for manufacturing a front member of an LED display, comprising:
forming a photosensitive layer on a support using a photosensitive composition containing at least one compound selected from the group consisting of a binder polymer and an ethylenic unsaturated compound, and a carbon nano-tube;
forming an uneven shape on a surface of the photosensitive layer opposite to a side on which the support is provided; and
patterning the photosensitive layer.

13. The method for manufacturing a front member of an LED display according to claim 12, wherein the forming an uneven shape is pressing a stamper having a moth-eye structure against the surface of the photosensitive layer opposite to the side on which the support is provided, thereby forming an uneven shape.
